(19) United States
(12) Patent Application Publication
(10) Pub. No.: US 2026/0107551 A1
(43) Pub. Date: Apr. 16, 2026

(54) Structure and Method for Gate-All-Around Device with Engineered Gate Structure

(71) Applicant: Taiwan Semiconductor Manufacturing Company, Ltd., Hsin-Chu (TW)

(72) Inventors: Chung-Yi SU, Taipei City (TW); Chin-You HSU, Hsinchu City (TW); Yueh Chang WU, Taipei City (TW); Juan Peng WONG, Hsinchu City (TW); Kuan-Ting LIU, Hsinchu City (TW); Hsien-Ming LEE, Changhua (TW); Chi On CHUI, Hsinchu City (TW)

(21) Appl. No.: 18/913,359

(22) Filed: Oct. 11, 2024

(51) Int. Cl. H01L 29/49; H01L 21/8238; H01L 27/092; H01L 29/06; H01L 29/08; H01L 29/423; H01L 29/66; H01L 29/775; H01L 29/786

(52) U.S. Cl. CPC H10D 64/665; H10D 30/014; H10D 30/43; H10D 30/6735; H10D 30/6757; H10D 62/121; H10D 62/151; H10D 64/017; H10D 84/017; H10D 84/0172; H10D 84/038; H10D 84/85

(57) ABSTRACT

The present disclosure provides a method that includes providing a substrate having a N region for n-type field-effect transistors (nFETs) and a P region for p-type field-effect transistors (pFETs); forming a gate dielectric layer in the N region and the P region to wrap around channels vertically stacked; performing a dipole treatment to a first portion of the gate dielectric layer in the N region while a second portion of the gate dielectric layer in the P region remain untreated; depositing a P metal layer in the gate dielectric layer in both the P region and the N region; and forming a fill metal layer on the P metal layer in both the P region and the N region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC structures (such as three-dimensional transistors) and processing and, for these advancements to be realized, similar developments in IC processing and manufacturing are needed. For example, device performance (such as device performance degradation associated with various defects) and fabrication cost of field-effect transistors become more challenging when device sizes continue to decrease. Although methods for addressing such a challenge have been generally adequate, they have not been entirely satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A illustrates a flowchart of an example method for making a semiconductor device in accordance with some embodiments of the present disclosure.

FIGS. 1B, 1C, 1D, 1E, 1F, 1G, and 1H illustrate flowcharts of an example method for making a semiconductor device in accordance with some embodiments of the present disclosure.

FIG. 2A illustrates a three-dimensional perspective view of an example semiconductor device in accordance with some embodiments of the present disclosure.

FIG. 2B illustrates a planar top view of an example semiconductor device in accordance with some embodiments of the present disclosure.

FIG. 3A illustrates a cross-sectional view of the semiconductor device of FIGS. 2A and 2B taken along line AA′ at an intermediate stage of an embodiment of the method of FIG. 1A in accordance with some embodiments of the present disclosure.

FIG. 3B illustrate cross-sectional views of the semiconductor device of FIGS. 2A and 2B taken along line BB′ at intermediate stages of an embodiment of the method of FIG. 1A in accordance with some embodiments of the present disclosure.

FIGS. 4A, 4B, 4C, 4D, and 4E illustrate cross-sectional views of the semiconductor device of FIGS. 2A and 2B taken along line BB′ at intermediate stages of an embodiment of the method of FIG. 1 in accordance with some embodiments of the present disclosure.

FIGS. 4F and 4G illustrate cross-sectional views of the semiconductor device of FIGS. 2A and 2B taken along line CC′ at intermediate stages of an embodiment of the method of FIG. 1A in accordance with some embodiments of the present disclosure.

FIGS. 5A and 5B illustrate cross-sectional views of the semiconductor device of FIGS. 2A and 2B taken along line CC', in portion, constructed in accordance with some embodiments of the present disclosure.

FIG. 6A illustrates a cross-sectional view of the semiconductor device of FIGS. 2A and 2B taken along line AA′ at an intermediate stage of an embodiment of the method of FIG. 1A in accordance with some embodiments of the present disclosure.

FIG. 6B illustrates a cross-sectional view of the semiconductor device of FIGS. 2A and 2B taken along line DD′ at an intermediate stage of an embodiment of the method of FIG. 1A in accordance with some embodiments of the present disclosure.

FIGS. 7A, 7B, 7C, 7D, 7E, 7F, 7G, and 7H illustrate cross-sectional views of the semiconductor device, in portion, of FIGS. 2A and 2B taken along line CC′ at intermediate stages of an embodiment of the method of FIG. 1B in accordance with some embodiments of the present disclosure.

FIGS. 8A, 8B, 8C, 8D, 8E, and 8F illustrate cross-sectional views of the semiconductor device, in portion, of FIGS. 2A and 2B taken along line CC′ at intermediate stages of an embodiment of the method of FIG. 1C in accordance with some embodiments of the present disclosure.

FIGS. 9A, 9B, 9C, 9D, 9E, and 9F illustrate cross-sectional views of the semiconductor device, in portion, of FIGS. 2A and 2B taken along line CC′ at intermediate stages of an embodiment of the method of FIG. 1D in accordance with some embodiments of the present disclosure.

FIGS. 10A, 10B, 10C, 10D, 10E, and 10F illustrate cross-sectional views of the semiconductor device, in portion, of FIGS. 2A and 2B taken along line CC′ at intermediate stages of an embodiment of the method of FIG. 1E in accordance with some embodiments of the present disclosure.

FIGS. 11A, 11B, 11C, 11D, 11E, and 11F illustrate cross-sectional views of the semiconductor device, in portion, of FIGS. 2A and 2B taken along line CC′ at intermediate stages of an embodiment of the method of FIG. 1F in accordance with some embodiments of the present disclosure.

FIGS. 12A, 12B, 12C, 12D, 12E, and 12F illustrate cross-sectional views of the semiconductor device, in portion, of FIGS. 2A and 2B taken along line CC′ at intermediate stages of an embodiment of the method of FIG. 1G in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices and the fabrication thereof, and more particularly to methods of fabricating field-effect transistors (FETs), such as fin-like FETs (FinFETs), gate-all-around FETs (GAA FETs), and/or other FETs. In the disclosed embodiments, a dummy interposer is implemented to reduce various defects to form GAA FETs and dipole treatment is applied to the gate structure with proper integration with the process of the dummy interposer to achieve enhanced performance of the corresponding FETs.

In the disclosed semiconductor fabrication to form a GAA FET device with multiple channels stack one over another, first semiconductor layers and second semiconductor layers are alternatively deposited to form a semiconductor stack; the semiconductor stack is patterned to form active regions (such as fin active regions) surrounded and separated from each other by an isolation structure, such as shallow trench isolation (STI) structure; a dummy gate structure, including dummy gate stacks and gate spacers, is formed over the active regions; the semiconductor stack in source/drain (S/D) regions are recessed; the first semiconductor layers are removed through the S/D trenches, resulting in channels vertical stacked and spaced with gaps; dummy interposers, such as dummy oxide interposers (DOI); are formed in the gaps; dummy interposers are laterally recessed and inner spacers are formed in the lateral recesses; S/D features are formed in the S/D trenches by epitaxial growth; dummy gate stacks are removed; the dummy interposers are further removed to release the channels vertically stacked and distanced from each other; and high-k metal gate stacks are formed to wrap around the channels. Especially, FETs to be formed include n-type FETs (nFETs) in nFET region and p-type FETs (pFETs) in pFET region while the high-k metal gate stacks include n-type gate stacks in the nFET region and p-type gate stacks in the pFET region designed and fabricated with different compositions such that the nFETs and the pFETs are optimized with reduced threshold voltages and enhanced performances.

The high-k metal gate stacks include a gate dielectric layer and a gate electrode disposed on the gate dielectric layer. The gate dielectric layer includes a high-k dielectric material layer and may further include an interfacial (IF) layer underlying the high-k dielectric material layer. The gate electrode includes a work function metal and a fill metal over the work function. During the formation of the high-k metal gate stacks, a dipole treatment is applied to the work function metal within one of the nFET region and the pFET region to tune work function, respectively. In the disclosed method, only one type of work function metal (such as a p-type work function metal, simply referred to as a P metal or p-metal) is deposited in both the nFET region and the pFET region, and a dipole treatment is applied to the work function metal within one of the nFET region and the pFET region (such as nFET region) to tune the work function in the nFET region. Accordingly, the method eliminates depositing both p-type work function metal and n-type work function metal (simply referred to as a n-metal or N metal); and etching one or both of the N metal and the P metal. The high-k dielectric material loss caused by work function metal etch is avoid; and processing efficiency and overall device performance are substantially improved.

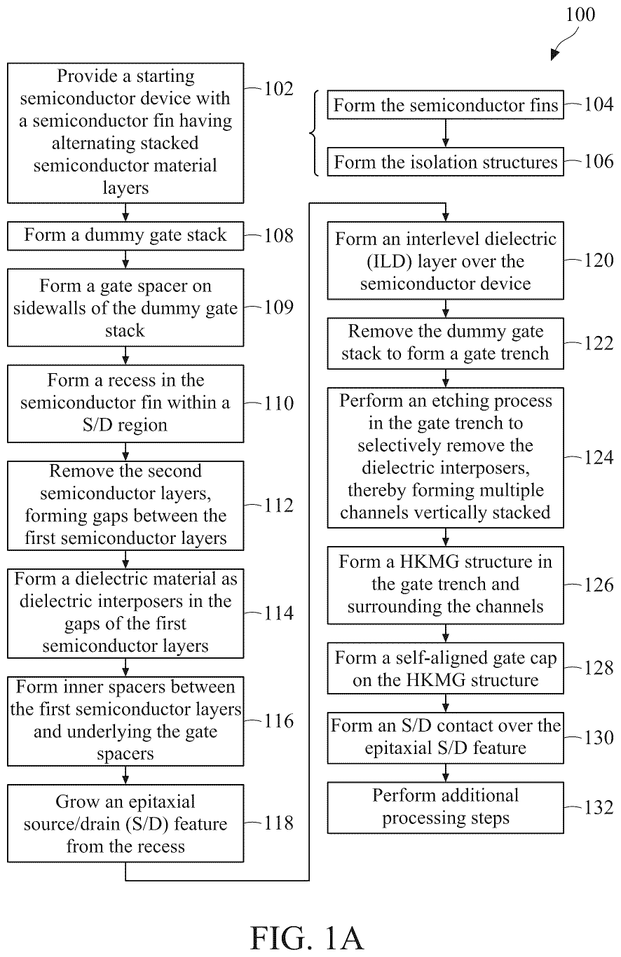

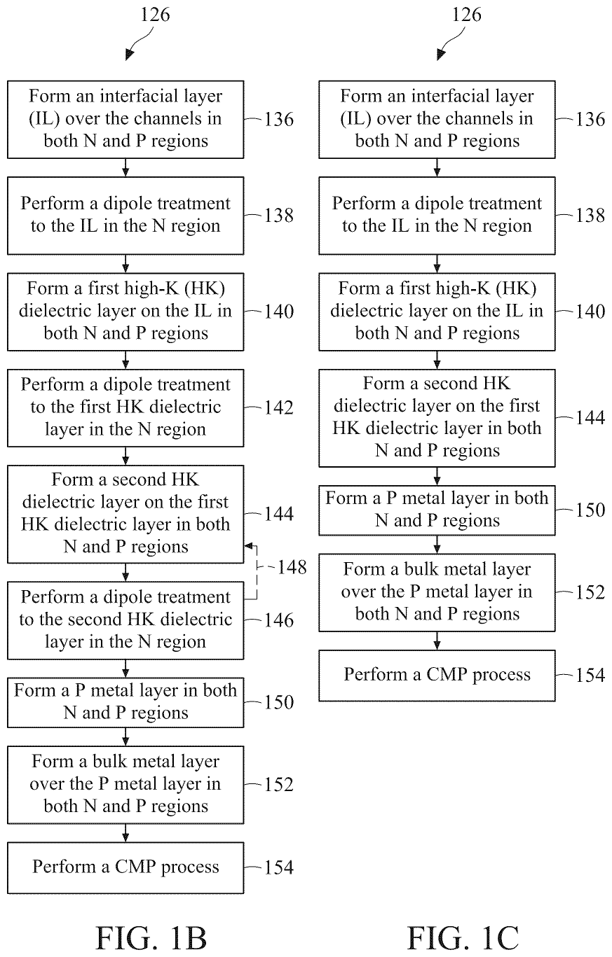

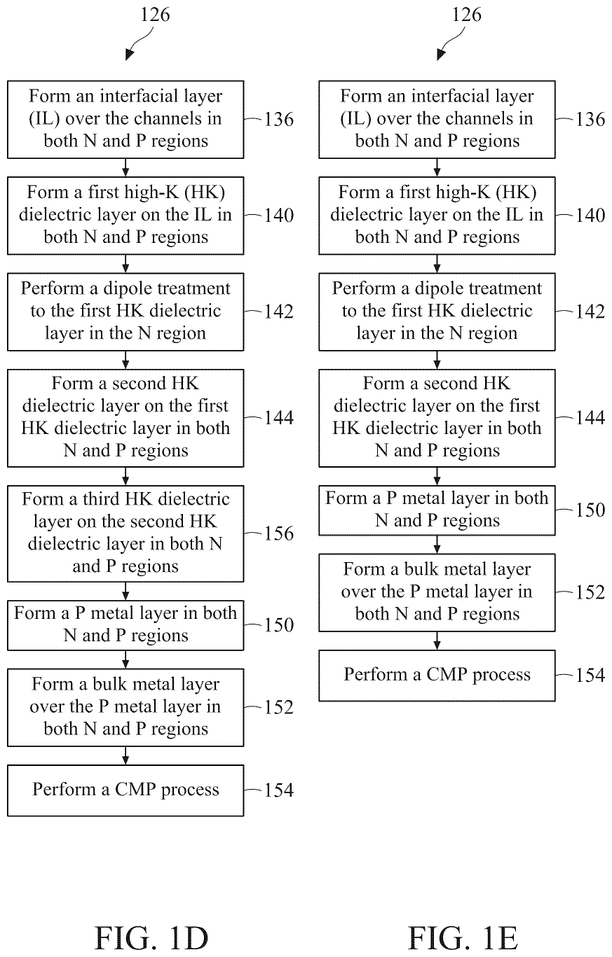

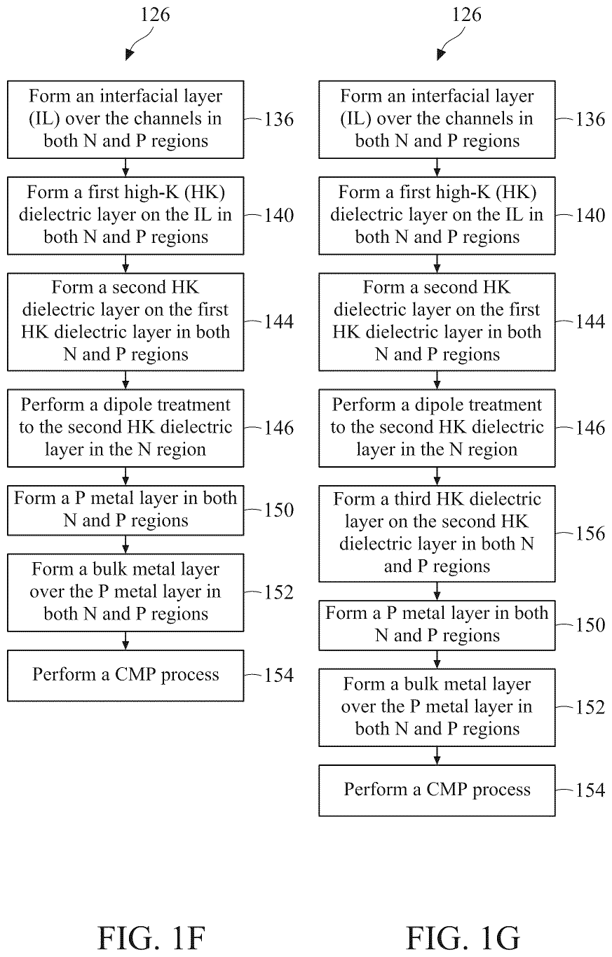

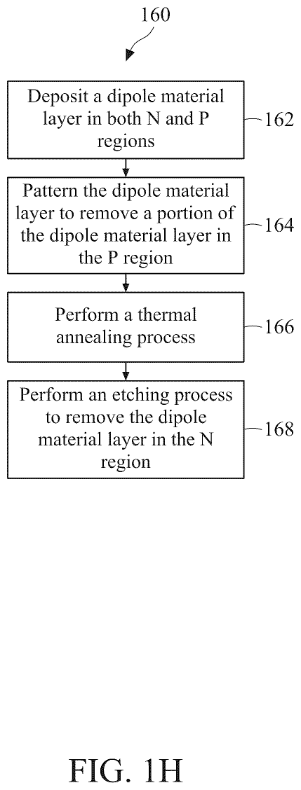

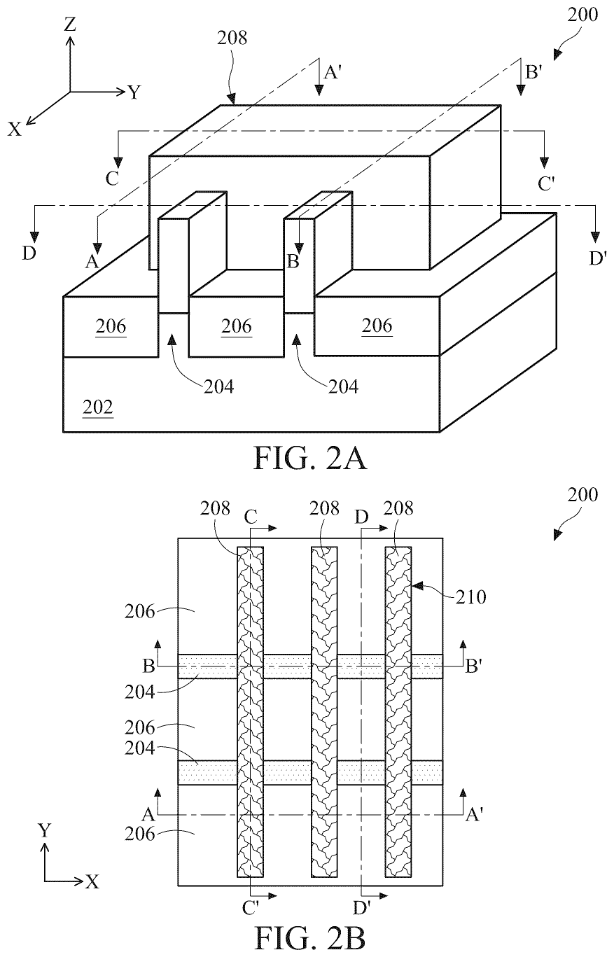

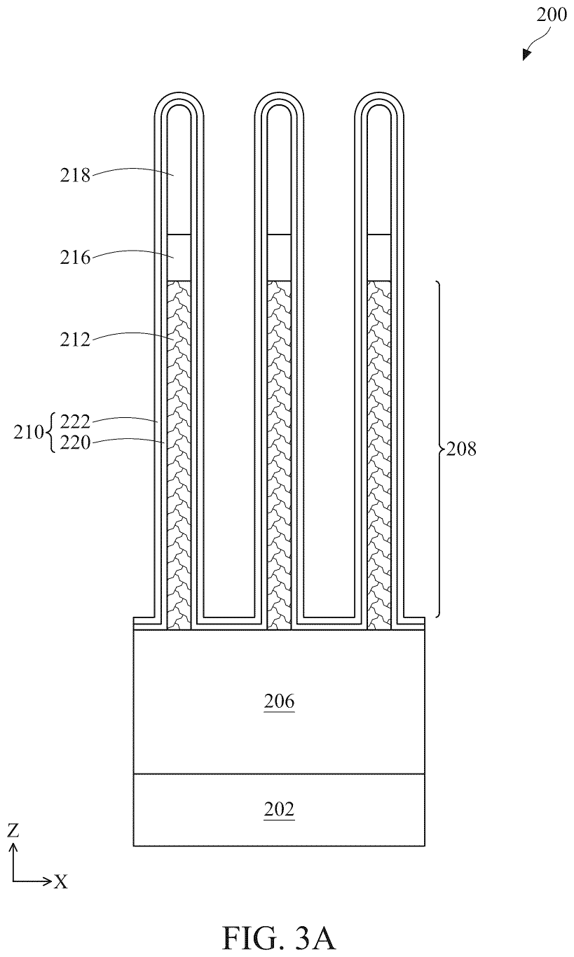

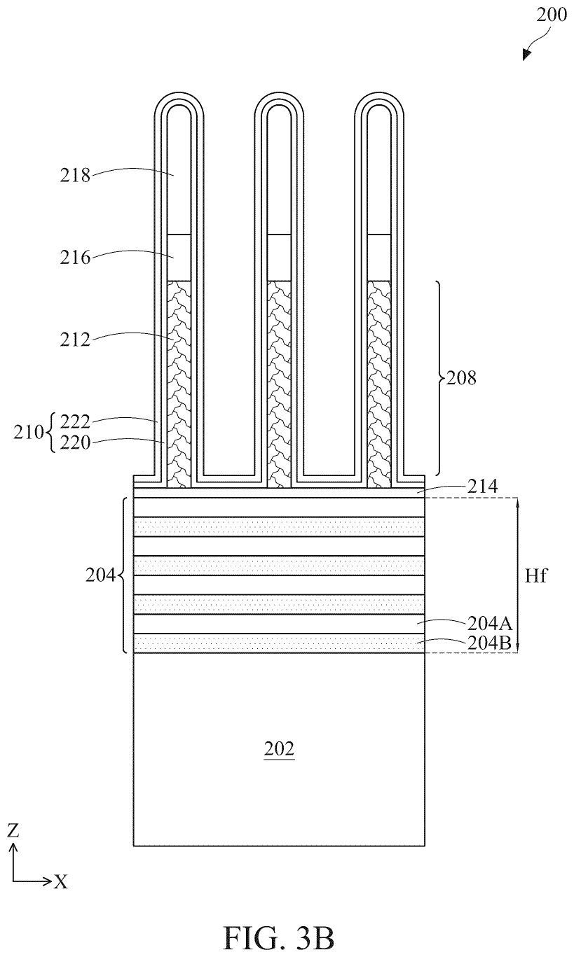

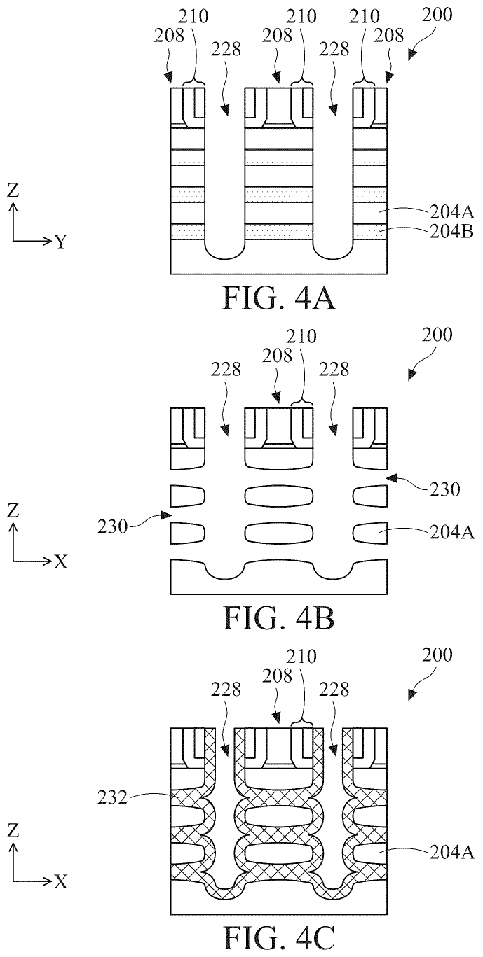

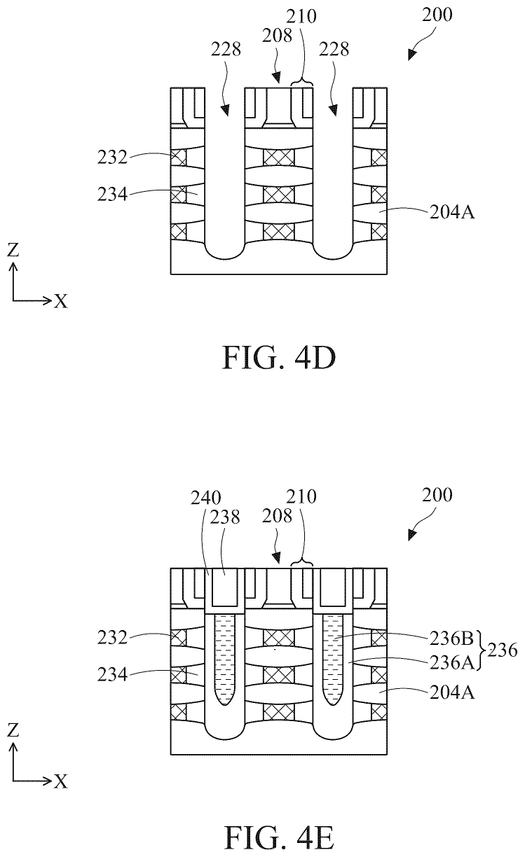

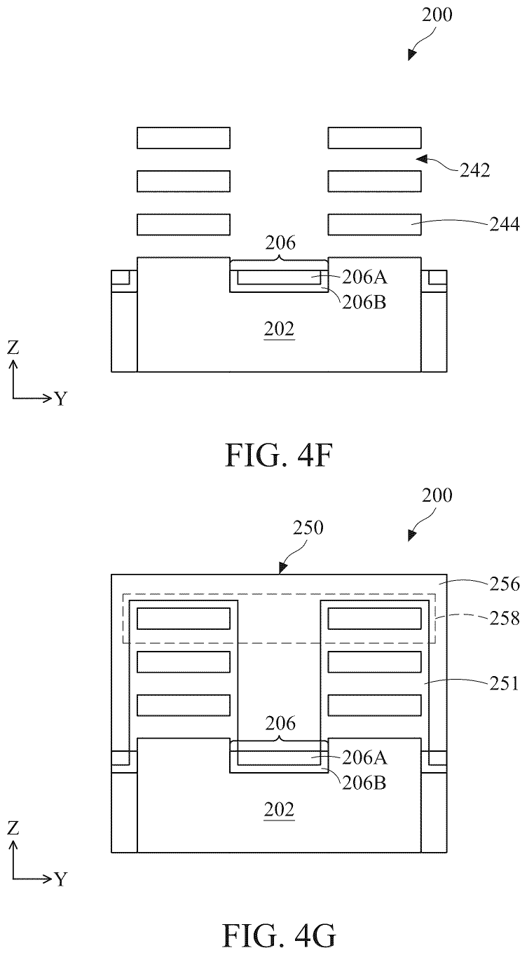

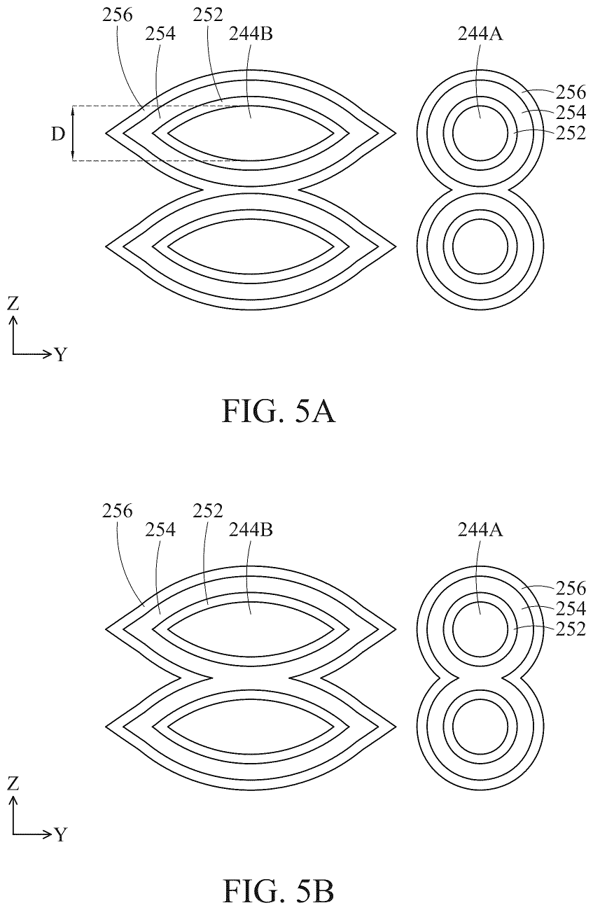

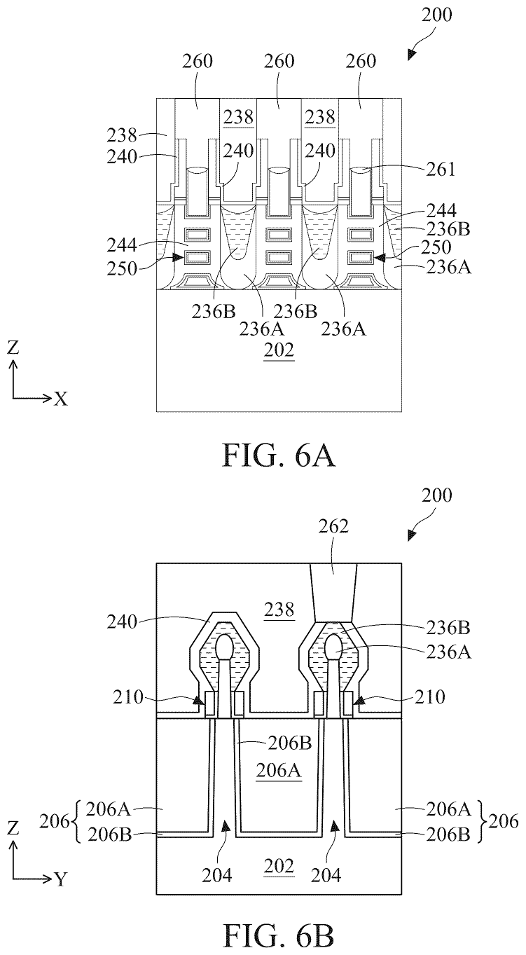

FIG. 1A illustrates a flow chart of a method 100 for forming a semiconductor device 200 (hereafter called “device 200” in short) in accordance with some embodiments of the present disclosure. The method 100 is merely an example and is not intended to limit the present disclosure beyond what is explicitly recited in the claims. Additional operations can be performed before, during, and after the method 100, and some operations described can be replaced, eliminated, or moved around for additional embodiments of the method. The method 100 is described below in conjunction with other figures, which illustrate various three-dimensional and cross-sectional views of the semiconductor structure 200 during intermediate steps of the method 100. In particular, FIG. 2A illustrates a three-dimensional view of the device 200; FIG. 2B illustrates a planar top view of the device 200; FIG. 3A illustrates a cross-sectional view of the device 200 taken along line AA′ as shown in FIGS. 2A and 2B; FIG. 3B illustrates a cross-sectional view of the device 200 taken along line BB′ as shown in FIGS. 2A and 2B; and FIGS. 4A, 4B, 4C, 4D, and 4E illustrate cross-sectional views of the semiconductor device of FIGS. 2A and 2B taken along line BB'; FIGS. 4F and 4G illustrate cross-sectional views of the semiconductor device of FIGS. 2A and 2B taken along line CC′; FIGS. 5A and 5B illustrate cross-sectional views of the semiconductor device of FIGS. 2A and 2B taken along line CC', in portion; FIG. 6A illustrates a cross-sectional view of the semiconductor device of FIGS. 2A and 2B taken along line AA'; and FIG. 6B illustrates a cross-sectional view of the semiconductor device of FIGS. 2A and 2B taken along line DD′ in accordance with some embodiments of the present disclosure.

The device 200 may be an intermediate device fabricated during processing of an integrated circuit (IC), or a portion thereof, that may include logic circuits, memory circuits, such as static random-access memory (SRAM), and/or other suitable circuits having active components (such as transistors, diodes, and imaging sensors) and passive components (such as resistors, capacitors, and inductors). In various examples, the active components include GAA FETs, p-type FETs (PFETs), n-type FETs (NFETs), fin-like FETs (FinFETs), metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations. For example, though the device 200 as illustrated is a GAA FET structure, the present disclosure may also provide embodiments for fabricating other three-dimensional FET devices.

Referring to FIGS. 1A and 2A-2B, the method 100 at operation 102 provides the device 200 that includes one or more active regions 204 protruding from a substrate 202 and separated by isolation structures 206 and a dummy gate stack 208 disposed over the substrate 202. The operation 102 includes a procedure 104 to form the semiconductor fins 204; and a procedure 106 to form the isolation structures 206 surrounding the active regions 204. In the disclosed embodiment, the active regions 204 are protruding above the isolation structures 206 and are also referred to as semiconductor fins 204. The device 200 may include other components, such as dummy gate stack 208, gate spacers 210 disposed on sidewalls of the dummy gate stack 208, various hard mask layers disposed over the dummy gate stack 208, barrier layers, other suitable layers, or combinations thereof, to be discussed in detail below.

The substrate 202 may include an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor, such as SiGe, GaAsP, AlInAs, AlGaAs, GaInAs, GaInP, GaInAsP, and/or other suitable materials. The substrate 202 may be a single-layer material having a uniform composition. Alternatively, the substrate 202 may include multiple material layers having similar or different compositions suitable for IC device manufacturing. In one example, the substrate 202 may be a silicon-on-insulator (SOI) substrate having a silicon layer formed on a silicon oxide layer. In another example, the substrate 202 may include a conductive layer, a semiconductor layer, a dielectric layer, other layers, or combinations thereof.

In some embodiments where the substrate 202 includes various doped regions, such as doped wells and source/drain regions, disposed in or on the substrate 202. The doped regions may be doped with p-type dopants, such as phosphorus or arsenic, and/or n-type dopants, such as boron or BF₂, depending on design requirements. The doped regions may be directly formed on the substrate 202 (such as a p-well structure, an n-well structure, or a dual-well structure) or using a raised structure (such as an epitaxial S/D feature). Doped regions may be formed by implantation of dopant atoms, in-situ doped epitaxial growth, diffusion, and/or other suitable techniques.

Each semiconductor fin 204 may be suitable for providing an n-type FET or a p-type FET. In some embodiments, the semiconductor fins 204 as illustrated herein may be suitable for providing FinFETs of a similar type, i.e., both n-type or both p-type. Alternatively, they may be suitable for providing FinFETs of opposite types, i.e., an n-type and a p-type. This configuration is for illustrative purposes only and is not intended to be limiting. The semiconductor fins 204 may be fabricated using suitable processes including photolithography and etch processes. The photolithography process may include forming a photoresist layer (or resist) overlying the substrate 202, exposing the resist to a pattern, performing post-exposure bake processes, and developing the resist to form a masking element (not shown) including the resist. The masking element is then used for etching recesses into the substrate 202, leaving the semiconductor fins 204 on the substrate 202. The etching process may include dry etching, wet etching, reactive ion etching (RIE), and/or other suitable processes.

Numerous other embodiments of methods for forming the semiconductor fins 204 may be suitable. For example, the semiconductor fins 204 may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

In the depicted embodiment, referring to FIGS. 3B and 3C for example, the semiconductor fin 204 may include alternating layers of semiconductor materials, e.g., first semiconductor material 204A and second semiconductor material 204B that is different from the first semiconductor material 204A in composition. In the following description, the layers of the first semiconductor material 204A and the layers of the second semiconductor material 204B are also referred to as first semiconductor material layers (or simply first semiconductor layers) 204A and second semiconductor material layers (or simply second semiconductor layers) 204B, respectively. In some example embodiments, the semiconductor fin 204 may include a total of three to ten alternating layers of semiconductor materials; of course, the present disclosure is not limited to such configuration. In the present disclosure, the first semiconductor material 204A includes silicon (Si), while the second semiconductor material 204B includes silicon germanium (SiGe). Either of the semiconductor materials 204A and 204B (or both) may be doped with a suitable dopant, such as a p-type dopant or an n-type dopant, for forming desired FETs. The semiconductor materials 204A and 204B may each be formed by an epitaxial process, such as, for example, a molecular beam epitaxy (MBE) process, a CVD process, and/or other suitable epitaxial growth processes.

In many embodiments, alternating layers of the semiconductor materials 204A and 204B are configured to provide nanowire or nanosheet devices such as GAA FETs, the details of forming which are provided below. GAA FETs have been introduced in effort to improve gate control by increasing gate-channel coupling, reduce OFF-state current, and reduce short-channel effects. A multi-gate device such as a GAA FET generally includes a gate structure that extends around its channel region (horizontal or vertical), providing access to the channel region on all sides. The GAA FETs are generally compatible with CMOS processes, allowing them to be aggressively scaled down while maintaining gate control and mitigating short-channel effects. Of course, the present disclosure is not limited to forming GAA FETs only and may provide other three-dimensional FETs such as FinFETs.

The isolation structures 206 are surrounding various active regions 204 and separate the active regions 204 one from another. The isolation structures 206 may include silicon oxide, silicon nitride, silicon oxynitride, fluoride-doped silicate glass (FSG), a low-k dielectric material, and/or other suitable materials. The isolation structures 206 may include shallow trench isolation (STI) features. In one embodiment, the isolation structures 206 are formed by etching trenches in the substrate 202 during the formation of the semiconductor fins 204. The trenches may then be filled with one or more dielectric material described above by a deposition process, followed by a chemical mechanical planarization (CMP) process. The isolation structures 206 may be subsequently recessed, such as selective etching, such that a top surface of the isolation structures 206 is below a top surface of the semiconductor fins 204, defining a fin height H_{f} of the semiconductor fins 204 for optimized coupling between the gate electrode and the channel. In some embodiments, the fin height of the semiconductor fins 204 ranges between 40 nm and 80 nm.

Other isolation structure such as field oxide, local oxidation of silicon (LOCOS), and/or other suitable structures may also be implemented as the isolation structures 206. Alternatively, the isolation structures 206 may include a multi-layer structure, for example, having one or more thermal oxide liner layers. The isolation structures 206 may be deposited by any suitable method, such as chemical vapor deposition (CVD), flowable CVD (FCVD), spin-on-glass (SOG), high-density plasma CVD (HDPCVD), high aspect ratio process (HARP), other suitable methods, or combinations thereof.

Referring to FIGS. 1A and 3A-3B, the method 100 proceeds to an operation 108 to form one or more dummy gate stack 208. In some embodiments, each dummy gate stack 208 serves as a placeholder for subsequently forming a high-k metal gate structure (HKMG; where “high-k” refers to a dielectric material with a dielectric constant greater than that of thermal silicon dioxide, which is about 3.9). The dummy gate stack 208 may include a dummy gate electrode 212 and various other material layers, such as a dielectric layer underlying the dummy gate electrode 212. In some embodiments, the dummy gate electrode 212 includes polysilicon. In the depicted embodiment, referring to FIG. 3B, the device 200 may include a dielectric layer 214 disposed between the semiconductor fins 204 and the dummy gate electrode 212 as an interfacial layer to the dummy gate stack 208. In some embodiments, the dummy gate stack 208 is formed by deposition and a patterning process. The patterning process further includes photolithography process and etching. In the present embodiment, a hard mask is further used in the patterning process to form the dummy gate stack 208. In the present example, the hard mask includes a first hard mask layer 216 disposed over the dummy gate electrode 212, and a second hard mask layer 218 disposed over the first hard mask layer 216. As will be discussed in detail below, portions of the dummy gate stack 208 are replaced with the HKMG during a gate replacement process after other components (e.g., the S/D features 236) of the device 200 are fabricated. The first hard mask layer 216 and second hard mask layer 218 may each include any suitable dielectric material, such as a semiconductor oxide and/or a semiconductor nitride. In one example, the first hard mask layer 216 includes silicon carbonitride, and the second hard mask layer 218 includes silicon oxide. Various material layers of the dummy gate stack 208 may be formed by any suitable process, such as CVD, PVD, ALD, other suitable processes, or combinations thereof. In some embodiments, the dummy gate stacks 208 are formed by a suitable procedure, such as a procedure that includes depositing various gate material including hard mask; and patterning the gate materials by a photolithography process and etching.

Still referring to FIGS. 1A and 3A-3B, the method 100 proceeds to an operation 109 form a gate spacer layer (or simply a spacer layer or gate spacers) 210 on the sidewalls of the dummy gate stack 208. The spacer layer 210 is formed by deposition and anisotropic etching. The spacer layer 210 may include multiple films of different composition. In some embodiments, the spacer layer 210 includes a first spacer layer 220 and a second spacer layer 222 disposed on the first spacer layer 220.

The first spacer layer 220 is deposited over the device 200. In some embodiments, the first spacer layer 220 is formed conformally over the device 200, including the semiconductor fins 204 and the dummy gate stacks 208. The first spacer layer 220 may include any suitable dielectric material, such as a nitrogen-containing dielectric material, and may be formed by any suitable method, such as ALD, CVD, PVD, other suitable methods, or combinations thereof. In the depicted embodiment, the first spacer layer 220 is formed by an ALD process. In some examples, the first spacer layer 220 may include silicon nitride, silicon carbonitride, silicon oxycarbonitride, other suitable dielectric materials, or combinations thereof. The second spacer layer 222 is formed on the first spacer layer 220. The second spacer layer 222 may be formed by deposition. Similar to the first spacer layer 220, the second spacer layer 222 may be formed conformally over the dummy gate stack 208 and the semiconductor fins 204. In some examples, the second spacer layer 222 includes a low-k dielectric material, silicon oxide, silicon oxycarbide, other suitable dielectric materials, or combinations thereof. The second spacer layer 222 may be formed by any suitable method, such as ALD, CVD, PVD, other suitable methods, or combinations thereof. In an example, each of the layers 220 and 222 is formed to have a thickness of less than about 10 nm. In the present embodiment, the first spacer layer 220 includes silicon nitride and the second spacer layer 222 includes a silicon oxide. The second spacer layer 222 may be disposable. The operation 109 may further include an anisotropic etch, such as plasma etch, to remove the portions thereof disposed on the top surfaces of the semiconductor fins 204 and the dummy gate stacks 208.

Now the subsequent operations of the method 100 are described with reference to FIGS. 1 and 4A-4G according to some embodiments. Some features are not shown in FIGS. 4A-4G for simplicity. For example, the substrate 202 is not shown in FIGS. 4A-4E. In another example, the hard mask, 216 and 218, is not shown in FIGS. 4A-4G.

Referring to FIGS. 1A and 4A, the method 100 at operation 110 removes a portion of the semiconductor fins 204 within a source/drain (S/D) region to form S/D trenches (or S/D recesses) 228 therein. In some embodiments, the method 100 forms the S/D trenches 228 by a suitable etching process, such as a dry etching process, a wet etching process, an RIE process, or a combination thereof. In some embodiments, the method 100 selectively removes the semiconductor fins 204 without etching or substantially etching portions of the spacer layers 220 and 222 formed on sidewalls of the dummy gate stacks 208. In some embodiments, upper portions of the hard mask 216 and 218 over the dummy gate stack 208 may be removed during the etching process to form the S/D trenches 228. The etching process at operation 110 may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof. The extent of which the semiconductor fins 204 is removed may be controlled by adjusting the duration of the etching process.

Referring to FIGS. 1A and 4B, the method 100 proceeds an operation 112 to fully remove the second semiconductor material layers 204B through the S/D trenches 228 by an etching process, thereby forming gaps 230 between the first semiconductor material layers 204A. As discussed above, the first semiconductor material 204A includes Si and the second semiconductor material 204B includes SiGe. During the operation 110, the etching process substantially etches both the semiconductor materials 204A and 204B. while the etching process at the operation 112 selectively etch the second semiconductor layers 204B or SiGe in the present embodiment. In an example embodiment, the etching process at the operation 112 includes a wet etching process that utilizes hydro fluoride (HF) solution and/or ammonium hydroxide (NH₄OH) solution as an etchant, which selectively removes SiGe.

Referring to FIGS. 1A and 4C, the method 100 proceeds an operation 114 to form a dielectric material 232 to fully fill the gaps 230. Thus, the dielectric material 232 replaces the second semiconductor layers 204B and functions as dielectric interposers (also referred to with the numeral 232) between the first semiconductor layers 204A. The dielectric interposers 232 include one or more proper dielectric material, such as silicon oxide, silicon nitride, silicon oxynitride, low-k dielectric material, other suitable dielectric material or a combination thereof. The dielectric interposes 232 are formed by a suitable technique, such as chemical vapor deposition (CVD), other suitable deposition method or a combination thereof. In some embodiments, the dielectric interposers 232 include silicon oxide deposited by low temperature technique, such as flowable CVD (FCVD), other low temperature deposition method, or a combination thereof. In some embodiments, the operation 114 may additionally include an anisotropic etch, such as a plasma etch, to remove excessive portions of the dielectric interposers 232.

Referring to FIGS. 1A and 4D, the method 100 proceeds an operation 116 to form inner spacers 234 underlying the gate spacer 210 on the sidewall of the dummy gate stack 208. The inner spacers 234 are formed vertically between the adjacent first semiconductor layers 204A. The operation 116 may include laterally etching; deposition; and anisotropic etching.

The lateral etching process selectively etch the dielectric interposers 232 such that the dielectric interposers 232 are laterally recessed, thereby forming undercuts underlying the gate spacers 210 on the sidewalls of the dummy gate stack 208. For example, the lateral etching process may include a wet etching process with an etchant to selectively recess the dielectric interposers 232. In some embodiments, the dielectric interposers 232 include silicon oxide, the etchant includes HF solution to selectively etch the dielectric interposers 232 of silicon oxide.

The deposition process of the operation 116 includes depositing one or more dielectric material to fill in the undercuts, thereby forming the inner spacers 234. The dielectric material of the inner spacers 234 includes one or more dielectric material different from the dielectric material of the dielectric interposers 232 in order to achieve etch selectivity during the channel release process described at later stages. In some embodiments, the dielectric interposers 232 include silicon oxide and the inner spacers 234 include silicon nitride. The deposition of the dielectric material at the operation 116 includes CVD, atomic layer deposition (ALD), other suitable deposition or a combination thereof.

The anisotropic etching process of the operation 116 is applied to trim the inner spacers 234 such that portions of the inner spacers 234 deposition on the sidewalls of the first semiconductor layers 204A are removed so that the source/drain features can be properly formed in the S/D trenches 228. In some embodiments, the isotropic etching process includes a plasma etch process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof.

Referring to FIGS. 1A and 4E, the method 100 proceeds to an operation 118 that epitaxially grows S/D features 236 starting from the S/D trenches 228. The S/D feature 236 may include multiple epitaxial semiconductor layers, such as a first semiconductor layer 236A and a second semiconductor layer 236B on the first semiconductor layer. In some embodiments, the first and second semiconductor layers differ in amount of dopant included therein. In some examples, the amount of dopant included in the first semiconductor layer 236A is less than that included in the second semiconductor layer 236B, to minimize potential leak currents and reduce the contact resistance. The dopant is in-situ introduced into the S/D feature 236 during the selective epitaxial growth. In some embodiments, the first and second semiconductor layers 236A/236B differ in composition to provide other advantages, such as strain effect to enhance the carrier mobility and the transistor speed. For example, the layers 236A and 236B include silicon and silicon germanium, respectively, or vice versa, depending on the transistor types.

The S/D feature 236 (i.e., the layers 236A and 236B included therein) may be formed by any suitable method, such as MBE, MOCVD, other suitable epitaxial growth processes, or combinations thereof. The S/D feature 236 may be suitable for a p-type FinFET device (e.g., a p-type epitaxial material) or alternatively, an n-type FinFET device (e.g., an n-type epitaxial material). The p-type epitaxial material may include one or more epitaxial layers of silicon germanium (epi SiGe), where the silicon germanium is doped with a p-type dopant such as boron, germanium, indium, and/or other p-type dopants. The n-type epitaxial material may include one or more epitaxial layers of silicon (epi Si) or silicon carbon (epi SiC), where the silicon or silicon carbon is doped with an n-type dopant such as arsenic, phosphorus, and/or other n-type dopants. Silicide may be additionally formed on the S/D feature 236 to decrease the contact resistance by a suitable procedure, such as metal deposition, annealing to react the metal with silicon to form the silicide.

Still referring to FIGS. 1A and 4E, the method 100 proceeds to an operation 120 to form an interlevel dielectric (ILD) layer 238 on the device 200 to provide isolation functions among various conductive features. The ILD layer 238 may be formed by deposition and CMP. The ILD layer 238 includes one or more dielectric material, such as silicon oxide, tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), low-k dielectric material or other suitable dielectric material. In various embodiments, the ILD layer 238 is deposited by CVD, HDPCVD, sub-atmospheric CVD (SACVD), HARP, a flowable CVD (FCVD), and/or a spin-on process. In some embodiments, forming the ILD layer 238 further includes performing a CMP process to planarize a top surface of the device 200, such that the top surfaces of the dummy gate stacks 208 are exposed. In some embodiments, a bottom contact etch-stop layer (BCESL) 240 is deposited between the ILD layer 238 and the substrate 202 with a composition different from that of the ILD layer 238, such as silicon nitride, to achieve etch selectivity. The BCESL 240 is conformally deposited on the semiconductor fins 204 and the S/D features 236.

Referring to FIGS. 1A and 4F, the method 100 includes an operation 122 to remove the dummy gate stack 208 by etch, resulting in a gate trench in the ILD layer 238. The operation 122 may additionally include patterning with photolithography process. For example, the dummy gate stack 208 for an n-type FET is removed by an etching process with a hard mask to cover the region for a p-type FET; and the dummy gate stack 208 for the p-type FET is removed by another etching process with another hard mask to cover the region for the n-type FET in order to fill them separately with different material, such as different metals with respective work functions to reduce the threshold voltages. Forming the gate trench may include one or more etching processes that are selective to the materials included in the dummy gate stacks 208 (e.g., polysilicon included in the dummy gate electrodes 212). The etching processes may include dry etching, wet etching, RIE, or other suitable etching methods, or combinations thereof. The isolation structures 206 is exposed in the gate trench. In some embodiments, the isolation structure 206 is a shallow trench isolation (STI) structure including multiple dielectric materials such as having one or more thermal oxide liner layers and a filling dielectric material (e.g., a low-k dielectric material, silicon oxide deposited by CVD, other suitable dielectric material or a combination thereof).

Still referring to FIGS. 1A and 4F, the method 100 also includes an operation 124 to perform an etching process to selectively remove the dielectric interposers 232 disposed in the gaps between the adjacent first semiconductor layers 204A in the gate trench, thereby forming gaps 242 between the first semiconductor layers 204A, such that portions of the first semiconductor layers 204A suspend in the gaps 242, functioning as channels 244 to the corresponding GAA devices. This operation is also referred to as a channel release process.

As discussed above, the first semiconductor material layers 204A include Si and the dielectric interposers 232 include a dielectric material, such as silicon oxide. Accordingly, the etching process at operation 124 selectively removes the dielectric interposers 232 without removing or substantially remove Si. In some embodiments, the etching process is an isotropic etching process (e.g., a dry etching process or a wet etching process), and the dielectric interposers 232, especially the portions of the dielectric interposers 232 in the corner regions adjacent the inner spacers 234, can be fully removed without residues. In an example embodiment, the method 100 that selectively removes the dielectric interposers 232 by a wet etching process utilizes hydrofluoric acid solution (HF) as an etchant.

By implementing the dielectric interposers 232 as sacrificial features, various advantages can be achieved. The channels 244 can be fully released without residue or with reduced residue. Even any residue is present, it is dielectric feature without changing the profile of the channels 244 in the corner regions. Overall, the GAA devices formed therein are improved with enhanced performance.

In some embodiments, the method 100 may include an operation to convert the channels 244 into a different semiconductor material, such as for strain effect. In some examples, the first semiconductor material 204A is converted from silicon into silicon germanium. This can be achieved by a suitable method, such as an ion implantation to introduce germanium into the channels 24. In some examples, after the removal of the dielectric interposers 232 by the operation 124, germanium is subsequently grown on the channels 24. Then an annealing process is applied to drive germanium into the channels 244.

In some embodiments, the channels 244 may have different shapes in section view, such as a round shape 244A for GAA FETs with a nanosheet structure or an elliptical shape (or an olive shape) 244B for GAA FETs with a nanowire structure, as illustrated in FIG. 5A. In some examples, the channels 244 have a dimension D ranging between 4 nm and 8 nm, optimized with other dimensions for better gate-channel coupling and enhanced device performance. The shape of the channels 244 may include rectangle (such as shown in FIG. 4F), olive shape or round shape (such as those shown in FIG. 5A), or other proper shape, depending on initial dimensions of the alternative semiconductor materials and the etching characteristics (such as isotropic etching and anisotropic etching) of the etching process to selectively remove the second semiconductor material 204B at the operation 112 and the etching process to selectively remove the dielectric interposers 232 at the operation 124.

Referring to FIGS. 1A and 4G, the method 100 proceeds to an operation 126 to form a metal gate structures 250 in the gate trenches. The metal gate structure 250 wraps around each of the multiple channels 244 vertically stacked. the metal gate structure 250 includes a gate dielectric layer 251 disposed on the channels 244, and a gate electrode 256 disposed on the gate dielectric layer 251. In some embodiments, the metal gate structure 250 is a high-k metal gate structure and includes a metal and a gate dielectric layer having a dielectric constant greater than that of silicon dioxide (about 3.9). The metal gate structure 250 is also referred to as high-k dielectric and metal gate (HKMG) structure 250. The formation of the metal gate structure 250 includes depositing various gate materials (including gate dielectric material and gate electrode material), dipole treatment and CMP.

During the operation 126, various material layers of the metal gate structure 250 are deposited in the gaps 242 formed between the channels 244 (the first semiconductor material 204A). The metal gate structure 250 includes a gate dielectric layer 251 including a high-k dielectric material layer 254 and a gate electrode 256. The gate dielectric layer 251 may further include an interfacial (IF) layer 252 (such as silicon oxide) underlying the high-k dielectric material layer 254, as illustrated in FIGS. 5A and 5B. Though not depicted, the metal electrode may include multiple metal or metal alloy layers, such as a work function metal layer formed over the high-k dielectric material layer 254, a bulk conductive layer formed over the work function metal layer, metal cap layers, other suitable layers, or combinations thereof. The high-k dielectric material layer 254 may include one or more high-k dielectric materials (or one or more layers of high-k dielectric materials), such as hafnium silicon oxide (HfSiO), hafnium oxide (HfO₂), alumina (Al₂O₃), zirconium oxide (ZrO₂), lanthanum oxide (La₂O₃), titanium oxide (TiO₂), yttrium oxide (Y₂O₃), strontium titanate (SrTiO₃), or a combination thereof. The work function metal layer may include any suitable material, such as titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof. In some embodiments, the high-k dielectric material layer 254 includes multiple high-k dielectric films of different compositions; a first subset of the high-k dielectric films is dipole treated and a second subset of the high-k dielectric films is not dipole treated.

The work function metal layer may include one or more material layers of the same or different types (i.e., both n-type work function metal or both p-type work function metal) in order to achieve a desired threshold voltage. The bulk conductive layer may include copper (Cu), tungsten (W), cobalt (Co), ruthenium (Ru), other suitable conductive materials, or combinations thereof. The metal gate structure 250 may include other material layers, such as a barrier layer, a glue layer, and/or a capping layer. The various layers of the metal gate structure 250 may be formed by any suitable method, such as CVD, ALD, PVD, plating, chemical oxidation, thermal oxidation, other suitable methods, or combinations thereof. Thereafter, the method 100 may perform one or more polishing process (e.g., CMP) to remove any excess conductive materials and planarize the top surface of the device 200.

However, the work function metal depositions and patterning to form the n-type work function layer and the p-type work function layer (simply N metal and P metal) experience various issues. For example, an Al-containing N metal has concerns of Al scavenging, which attracts oxygen from HK dielectric material and causes HK dielectric reliability issue. In another example, P metal patterning process including lithography process and etch before N metal deposition will cause damage to the HK dielectric layer in nFET regions, leading to HK dielectric loss. In yet another example, N metal and P metal at the interface will inter-diffuse and change the compositions and increase threshold voltages Vt for both nFET and pFET. This effect is referred to as MBE metal boundary effect.

In the disclosed embodiments, the formation of the metal gate structure at operation 126 is designed to effectively eliminate the issues described above and can enhance device performance without causing reliability issues and HK loss. The disclosed method of the operation 126 includes depositing only one type-work function metal layer (such as P metal) in both regions for nFETs and pFETs (or simply referred to N region and P region) and performing one or more dipole treatment to the gate dielectric layer 251 in only one of N region and P region (such as a N region), thereby tuning the work function of the gate dielectric layer 251 in that region (such as N region). Collectively, the threshold voltages for both nFETs and pFETs are reduced and optimized.

Still referring to FIGS. 4G and 5A, the gate materials, including the IF layer 252 and the high-k dielectric material layer 254 are deposited to wrap around each of the channels 244. One or more dipole treatment is applied to the gate dielectric layer 251 in the N region while the gate dielectric layer 251 in the P region is covered and is not treated. Thereafter, the gate electrode 256, including a P metal layer, is deposited in both N region and P region. A fill metal layer may be further deposited on the P metal layer, and a CMP process is applied thereafter. In the disclosed embodiment, the P metal layer directly contacts the gate dielectric layer in the N region and the P region, and the fill metal layer directly contacts the P metal layer in the N region and the P region. In some embodiments, the gate electrode 256 further includes a glue layer interposed between the P metal layer and the fill metal layer. The glue layer is a titanium nitride. In this case, the glue layer contacts the P metal layer in the N region and the P region. In some embodiment, the glue layer directly contacts the P metal layer in the N region and the P region.

In some embodiments, the glue layer is located in the gate trench above the first channels and outside of space between two first channels. In some embodiments, a portion of the P metal is located in between HK layer and the glue layer. In some embodiments, the fill metal is located in the gate trench above the first channels and outside of space between two first channels, wherein the fill metal comprises Tungsten.

The gate electrode 256 further vertically extends above the semiconductor fin 204. In some embodiments, the high-k (HK) dielectric material layer 254 is deposited on the IF layer 252 such that the high-k dielectric material layer 254 deposited on top of one channel 244 is merged with the high-k dielectric material layer 254 deposited on bottom of another channel 244, as illustrated in FIG. 5B. This merged structure may alleviate parasitic capacitance. Accordingly, the gate electrode 256 is eliminated from the region where the high-k dielectric material layer 254 merges. The gate electrode 256 includes a P metal, such as titanium nitride (TiN) on both N region and P region. In some embodiments, the gate electrode 256 further includes bulk metal layer, such as a bulk metal described above. The work functions can also be tuned through different configurations of various material layers of the gate dielectric layer 251. The formation of the metal gate structure 250 at the operation 126, including deposition and dipole treatment, will be further described later with reference to FIGS. 1B through 1G and other figures.

Referring to FIGS. 1A and 6A, in some embodiments, the method 100 may include an operation 128 to form a self-aligned gate cap (SAGC) 260 on the top of the metal gate structure 250. The SAGC 260 includes one or more dielectric material different from that of the ILD layer 238 in composition to achieve etch selectivity. In some embodiments, the SAGC 260 may function to form self-aligned via landing on the metal gate structure 250. The SAGC 260 may be formed by a suitable procedure, such as a procedure that includes selectively etching to recess the metal gate structure 250; and selectively depositing a dielectric material to fill the recess. In some embodiments, the SAGC 260 may be formed by a procedure that includes selectively etching to recess the metal gate structure 250; and depositing a dielectric material to fill the recess; and performing a CMP process to remove portions of the dielectric material above the ILD layer 238 and planarize the SAGC 260. Thus, when a via feature connecting to the gate electrode 256 is formed on the gate electrode 256 by etch and deposition, the etching process is designed to selectively etch the SAGC 260 and therefore is constrained to be self-aligned to the gate electrode 256. In some embodiments, a conductive cap 261 may be disposed on the top of the metal gate structure 250. The conductive cap 261 may include metal, metal alloy, other conductive material or combinations thereof. The conductive cap 261 is different from the gate electrode 256 in composition as an interface to prevent from interdiffusion, provide protection from etching to the gate electrode 256 and reduce contact resistance between the gate contact and the gate electrode 256. In some embodiments, the conductive cap 261 and the fill metal layer 256B include copper, tungsten, cobalt, other suitable metal, metal alloy or a combination thereof. In some embodiments, the semiconductor device 200 may eliminate the SAGC 260 so that the ILD layer 238 or other dielectric layer is directly disposed on the metal gate structure 250. In alternative embodiment, due to the limited space (in X-direction; if it is short channel transistor), the glue layer completely filled into top gate (no metal fill). However, the amount of glue layer in the top gate is larger than the amount of glue layer in between two sheets. If it is the long channel, the filled metal may be filled into top gate, but not filled into sheet-sheet region.

Referring to FIGS. 1A and 6B, the method 100 may include an operation 130 to a S/D contact 262 landing on the S/D feature 236 to be in electrical contact with the corresponding S/D features 236. Each S/D contact 262 may include one or more conductive layers and may be formed by a procedure that includes patterning to form a contact hole in the ILD layer 238, and deposition to fill the contact hole with one or more conductive material. The patterning process includes photolithography process and etching. The deposition may use any suitable method such as ALD, CVD, PVD, plating, and/or other suitable processes. In some embodiments, each S/D contact 262 includes a seed metal layer and a fill metal layer. In various embodiments, the seed metal layer includes cobalt (Co), tungsten (W), ruthenium (Ru), nickel (Ni), other suitable metals, or combinations thereof. The fill metal layer may include copper (Cu), tungsten (W), aluminum (Al), cobalt (Co), other suitable materials, or combinations thereof. As illustrated in FIG. 6B, the isolation structure 206 include multiple dielectric materials such as a thermal oxide liner layer 206B and a filling dielectric material 206A (e.g., a low-k dielectric material, silicon oxide deposited by CVD, other suitable dielectric material or a combination thereof).

Referring to FIG. 1A, the method 100 at operation 132 may perform additional processing steps. For example, additional vertical interconnect features such as metal vias, horizontal interconnect features such as metal lines, and/or multilayer interconnect features such as metal layers and interlayer dielectrics can be formed over the device 200. The various interconnect features may implement various conductive materials including copper (Cu), tungsten (W), cobalt (Co), aluminum (Al), titanium (Ti), tantalum (Ta), platinum (Pt), molybdenum (Mo), silver (Ag), gold (Au), manganese (Mn), zirconium (Zr), ruthenium (Ru), their respective alloys, metal silicide, other suitable materials, or combinations thereof. The metal silicide may include nickel silicide, cobalt silicide, tungsten silicide, tantalum silicide, titanium silicide, platinum silicide, erbium silicide, palladium silicide, other suitable metal silicide, or combinations thereof.

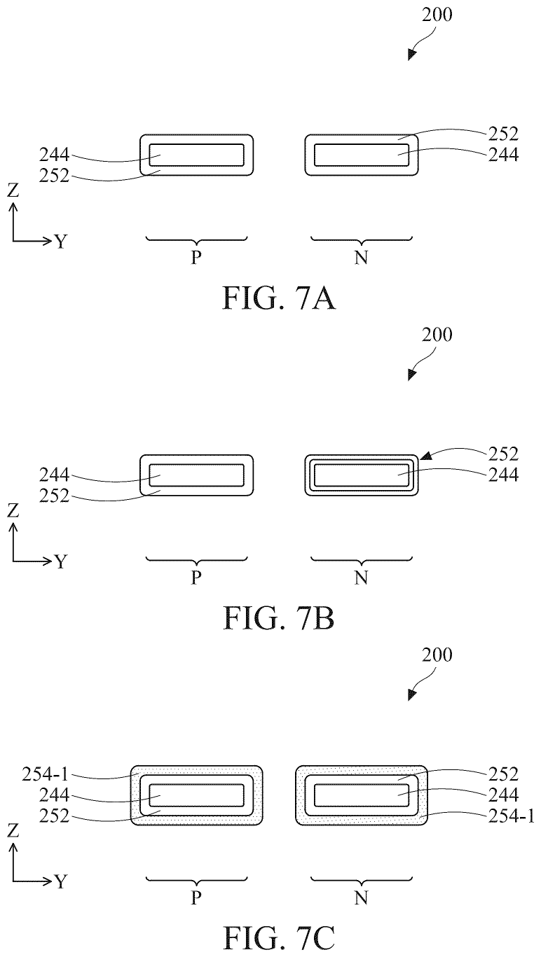

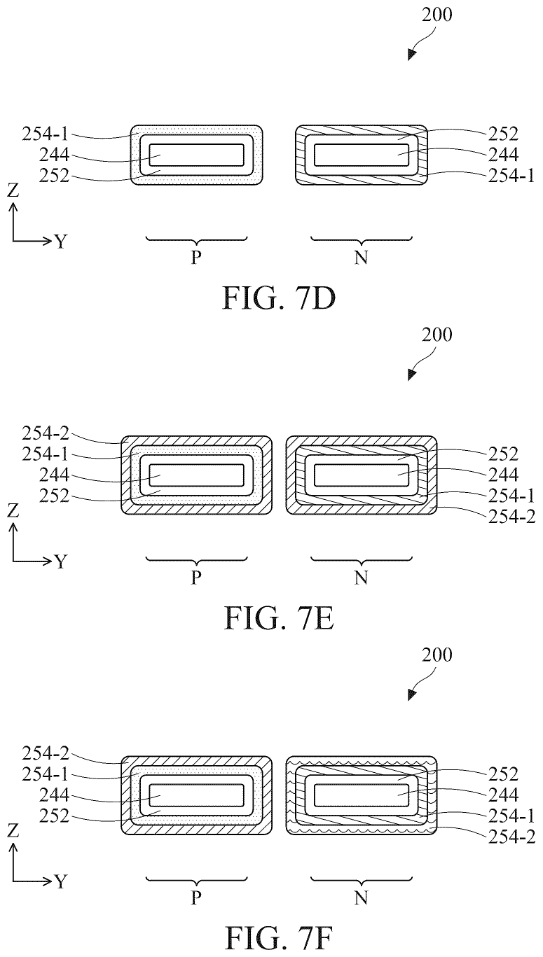

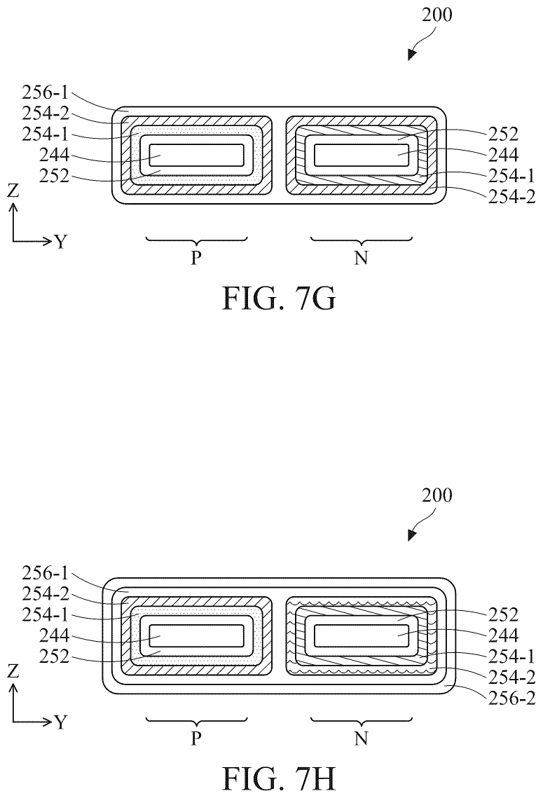

Referring back to the method 100 in FIG. 1A, the operation 126 to form the metal gate structure 250 includes depositions of various gate material and one or more dipole treatments to the gate dielectric layer 251, as described above. The operation 126 is further described in detail with reference to FIGS. 1B through 1G and other figures, such FIGS. 7A through 7H, according to various embodiments. FIGS. 1B through 1G are flowcharts of the method 126 according to various embodiments. FIGS. 7A through 7H are sectional views of the semiconductor device 200 at various fabrication stages according to some embodiments. Note that only a portion 258 of the semiconductor device 200 in FIG. 4G is illustrated in FIGS. 7A through 7H for simplicity.

Referring to FIGS. 1B and 7A, the method 126 includes an operation 136 by forming an interfacial layer 252 on the channels 244 in both N region (“N” in FIG. 7A) and P region (“P” in FIG. 7A). In the disclosed embodiment, the interfacial layer 252 is wrapping around each of the channels 244. The interfacial layer 252 may include silicon oxide, other suitable dielectric material, or a combination thereof. The interfacial layer 252 may be formed by applying a wet solution of hydrochloric acid-hydrogen peroxide-water mixture to the channels 244, thermal oxidation, atomic layer deposition (ALD), other suitable technique or a combination thereof.

Referring to FIGS. 1B and 7B, the method 126 includes an operation 138 by performing a dipole treatment to the interfacial layer 252 in the N region while the P region is not treated. The dipole treatment includes multiple steps, such as the dipole treatment process 160 illustrated in FIG. 1H. The dipole treatment process 160 includes: at block 162, depositing a dipole material layer, such as lanthanum oxide (LaO, or La₂O₃) by a suitable method, such as ALD; at block 164, patterning the dipole layer using a lithography process and etch to remove a portion of the dipole material layer such that the dipole material layer is only remain in the N region; at block 166, performing a thermal annealing process so that the lanthanum is diffused into the interfacial layer 252 in the N region; and at block 168, performing an etching process to remove the dipole layer.

In some embodiments, the etching process at the block 168 includes a wet etching process using an etchant to remove LaO. In the disclosed example, the etchant includes a hydrochloric acid peroxide mixture (HPM). In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer, such as LaO by a suitable method, such as ALD; forming a mask layer using a lithography process and etch such that the dipole layer in the P region is covered while that the dipole layer in the N region is exposed; performing a thermal annealing process so that the lanthanum is diffused into the interfacial layer 252 in the N region; removing the mask layer (for example, stripping or plasma ashing to remove the patterned photoresist layer when the patterned photoresist layer is used as the mask layer); and etching to remove the dipole layer. Thus, the interfacial layer 252 in the N region is treated and is different from the interfacial layer 252 in the P region in composition. Particularly, the interfacial layer 252 in the N region includes more lanthanum that the interfacial layer 252 in the P region. In some embodiments, the lanthanum concentration Cₙ₀ of the interfacial layer 252 in the N region and the lanthanum concentration Cₚ₀ of the interfacial layer 252 in the P region define a ratio Cₙ₀/Cₚ₀ being greater than 6. In some embodiments, the ratio Cₙ₀/Cₚ₀ ranges between 6 and 16.

Referring to FIGS. 1B and 7C, the method 126 proceeds to an operation 140 by forming a first high-k (HK) dielectric layer 254-1 over the interfacial layer 252 in both N region and P region after the dipole treatment at the operation 138. In some embodiments, the first HK dielectric layer 254-1 includes hafnium oxide (HfO) or zirconium oxide (ZrO). The first HK dielectric layer 254-1 is deposited by ALD, other suitable method or a combination thereof.

Referring to FIGS. 1B and 7D, the method 126 proceeds to an operation 142 by performing a dipole treatment to the first HK dielectric layer 254-1 in the N region while the P region is not treated. The dipole treatment at the operation 142 is similar to the dipole treatment at the operation 138. In some embodiments, the dipole treatment includes multiple steps: depositing a dipole material layer, such as lanthanum oxide by a suitable method, such as ALD; patterning the dipole layer using a lithography process and etch such that the dipole layer is only remain in the N region; performing a thermal annealing process so that the lanthanum is diffused into the first HK dielectric layer 254-1 in the N region; and etching to remove the dipole layer. In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer, such as LaO, by a suitable method, such as ALD; forming a mask layer using a lithography process and etch such that the dipole layer in the P region is covered while that the dipole layer in the N region is exposed; performing a thermal annealing process so that the lanthanum is diffused into the first HK dielectric layer 254-1 in the N region; removing the mask layer (for example, stripping or plasma ashing to remove the patterned photoresist layer when the patterned photoresist layer is used as the mask layer); and etching to remove the dipole layer. Thus, the first HK dielectric layer 254-1 in the N region is treated and is different from the first HK dielectric layer 254-1 in the P region in composition. Particularly, the first HK dielectric layer 254-1 in the N region includes more lanthanum that the first HK dielectric layer 254-1 in the P region. The lanthanum concentration of the first HK dielectric layer 254-1 in the N region is referred to as Cₙ₁, and the lanthanum concentration of the first HK dielectric layer 254-1 in the P region is referred to as Cₚ₁. In some embodiments, a ratio Cₙ₁/Cₚ₁ is greater than 6. In some embodiments, the ratio Cₙ₁/Cₚ₁ ranges between 6 and 16.

In some embodiments, the dipole treatment at the operation 142 may drive the dipole material, such as lanthanum, to diffuse into the interface between the interfacial layer 252 and the HK dielectric layer 254 (such as the first HK dielectric layer 254-1) to form an interface layer therebetween with a composition of a HK dielectric material (such as hafnium oxide or zirconium oxide), lanthanum and silicon oxide.

Referring to FIGS. 1B and 7E, the method 126 proceeds to an operation 144 by forming a second high-k (HK) dielectric layer 254-2 over the first HK dielectric layer 254-1 in both N region and P region after the dipole treatment at the operation 142. The second HK dielectric layer 254-2 is deposited by ALD, other suitable method or a combination thereof. In some embodiments, the second HK dielectric layer 254-2 includes a HK dielectric material different from that of the first HK dielectric layer 254-1. For example, the first HK dielectric layer 254-1 includes HfO and the second HK dielectric layer 254-2 includes ZrO. In another example, the first HK dielectric layer 254-1 includes ZrO and the second HK dielectric layer 254-2 includes HfO. In some alternative embodiments, the first and second HK dielectric layers 254-1 and 254-2 include a same composition, such as HfO (or ZrO).

Referring to FIGS. 1B and 7F, the method 126 proceeds to an operation 146 by performing a dipole treatment to the second HK dielectric layer 254-2 in the N region while the P region is not treated. The dipole treatment at the operation 146 is similar to the dipole treatment at the operation 142. In some embodiments, the dipole treatment includes multiple steps: depositing a dipole material layer, such as lanthanum oxide by a suitable method, such as ALD; patterning the dipole layer using a lithography process and etch such that the dipole layer is only remain in the N region; performing a thermal annealing process so that the lanthanum is diffused into the second HK dielectric layer 254-2 in the N region; and etching to remove the dipole layer. In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer by a suitable method, such as ALD; forming a mask layer using a lithography process and etch such that the dipole layer in the P region is covered while that the dipole layer in the N region is exposed; performing a thermal annealing process so that the lanthanum is diffused into the second HK dielectric layer 254-2 in the N region; removing the mask layer (for example, stripping or plasma ashing to remove the patterned photoresist layer when the patterned photoresist layer is used as the mask layer); and etching to remove the dipole layer. Thus, the second HK dielectric layer 254-2 in the N region is treated and includes lanthanum. The lanthanum concentration of the second HK dielectric layer 254-2 in the N region is referred to as Cₙ₂, and the lanthanum concentration of the second HK dielectric layer 254-2 in the P region is referred to as Cₚ₂. In some embodiments, a ratio Cₙ₂/Cₚ₂ is greater than 6. In some embodiments, the ratio Cₙ₂/Cₚ₂ ranges between 6 and 16.

The method 126 may include an operation 148 to repeat the operations 144 and 146 a number of times, thereby forming one or more additional HK dielectric layer, performing dipole treatments to those HK dielectric layers, respectively. For example, forming a third HK dielectric layer 254-3 (not shown) and performing a dipole treatment to the third HK dielectric layer 254-3. The number of the operations 144 and 146 to be implemented depends on individual applications so that the final structure is optimized.

Referring to FIGS. 1B and 7G, the method 126 proceeds to an operation 150 by forming a metal layer of a P metal (or simply referred to as a P metal layer) 256-1 on the gate dielectric layer 251 (which includes the interfacial layer 252 and one or more HK dielectric material layer 254) in both the P region and the N region. The P metal layer 256-1 includes an aluminum-free metal material. In some embodiments, the P metal layer 256-1 includes a metal, metal compound with a work function being equal to or greater than 4.7 eV. In the present embodiment, the P metal layer 256-1 is a titanium nitride (TiN) layer. In various embodiments, the P metal layer 256-1 includes titanium nitride (TiN), tantalum nitride (TaN), tungsten nitride (WN) or a combination thereof. The P metal layer 256-1 is deposited by physical vapor deposition (PVD), ALD, other suitable method or a combination thereof.

Referring to FIGS. 1B and 7H, the method 126 may include an operation 152 by forming a fill metal (or bulk metal) layer 256-2 on the P metal layer 256-1. In various embodiments, the fill metal layer 256-2 includes cobalt (Co), tungsten (W), ruthenium (Ru), nickel (Ni), other suitable metals, or combinations thereof. The fill metal layer may include copper (Cu), tungsten (W), aluminum (Al), cobalt (Co), other suitable materials, or combinations thereof. The fill metal layer 256-2 may be formed by PVD, plating, ALD, other suitable method or a combination thereof. In some embodiments, the fill metal layer 256-2 includes a seed layer formed by PVD, and a bulk metal layer formed on the seed layer by plating.

In some embodiments, a glue layer may be formed before the fill layer. In one embodiment, the glue layer is titanium nitride (TiN) layer. In some embodiments, the glue layer completely fills into spacings between channels 244. In furtherance of the embodiments, the fill metal layer 256-2 is only disposed in the gate trench above the channels 244, and the fill metal layer is free from the spacings between the channels. In this case, the numeral 256-2 collectively refers to the glue layer and the fill metal layer disposed on the glue layer. In some embodiments, the glue layer completely fills the spacings between the channels and the gate trench so that the fill metal layer is eliminated and replaced by the glue layer. In this case, the numeral 256-2 represents the glue layer. In various embodiments wherein the glue layer is present, the glue layer contacts the P metal layer 256-1 in the P region and N region.

In some embodiments, the glue layer is located in the gate trench above the first channels and outside of space between two first channels. In some embodiments, a portion of the P metal is located in between HK layer and the glue layer. In some embodiments, the fill metal is located in the gate trench above the first channels and outside of space between two first channels, wherein the fill metal comprises Tungsten.

The method 126 proceeds to an operation 154 by performing a chemical mechanical polishing (CMP) process to remove excessive gate materials and planarize the top surface, as illustrated in FIG. 4G.

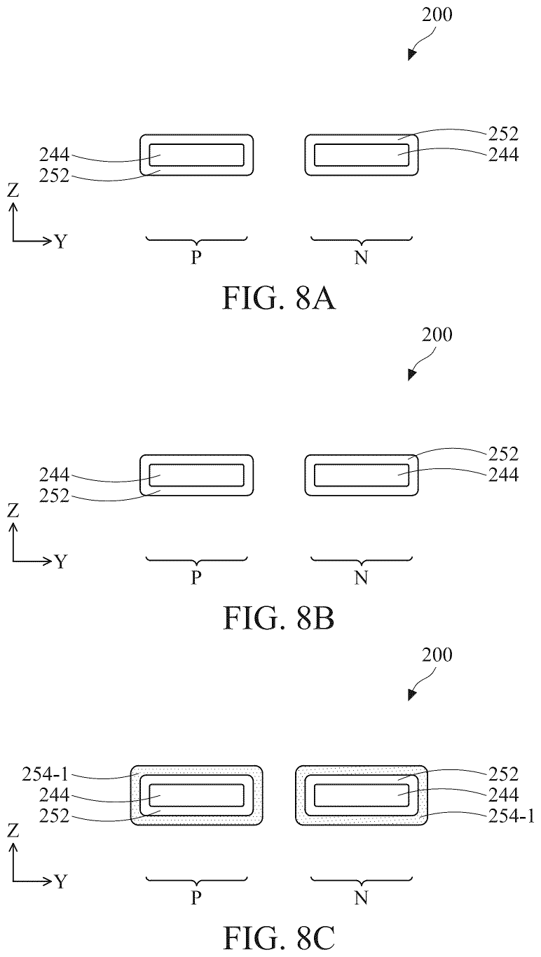

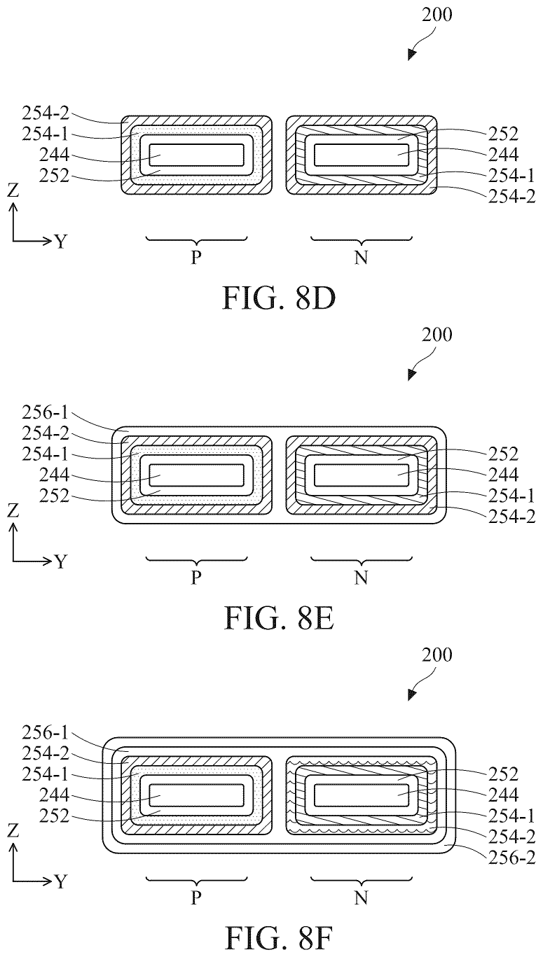

FIG. 1C is a flowchart of the method 126 constructed according to some embodiments. FIGS. 8A through 8F are sectional views of the semiconductor device 200 at various fabrication stages according to some embodiments. Note that only a portion 258 of the semiconductor device 200 in FIG. 4G is illustrated in FIGS. 8A through 8F for simplicity.

Referring to FIGS. 1C and 8A, the method 126 includes an operation 136 by forming an interfacial layer 252 on the channels 244 in both N region and P region. In the disclosed embodiment, the interfacial layer 252 is wrapping around each of the channels 244. The interfacial layer 252 may include silicon oxide, other suitable dielectric material, or a combination thereof. The interfacial layer 252 may be formed by applying a wet solution of hydrochloric acid-hydrogen peroxide-water mixture (SC-2) to the channels 244, thermal oxidation, atomic layer deposition (ALD), other suitable technique or a combination thereof.

Referring to FIGS. 1C and 8B, the method 126 includes an operation 138 by performing a dipole treatment to the interfacial layer 252 in the N region while the P region is not treated. In some embodiments, the dipole treatment includes multiple steps: depositing a dipole material layer, such as lanthanum oxide (LaO, or La₂O₃) by a suitable method, such as ALD; patterning the dipole layer using a lithography process and etch such that the dipole layer is only remain in the N region; performing a thermal annealing process so that the lanthanum is diffused into the interfacial layer 252 in the N region; and etching to remove the dipole layer. In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer, such as LaO by a suitable method, such as ALD; forming a mask layer using a lithography process and etch such that the dipole layer in the P region is covered while that the dipole layer in the N region is exposed; performing a thermal annealing process so that the lanthanum is diffused into the interfacial layer 252 in the N region; removing the mask layer (for example, stripping or plasma ashing to remove the patterned photoresist layer when the patterned photoresist layer is used as the mask layer); and etching to remove the dipole layer. Thus, the interfacial layer 252 in the N region is treated and is different from the interfacial layer 252 in the P region in composition. Particularly, the interfacial layer 252 in the N region includes more lanthanum that the interfacial layer 252 in the P region. In some embodiments, the lanthanum concentration Cₙ₀ of the interfacial layer 252 in the N region and the lanthanum concentration Cₚ₀ of the interfacial layer 252 in the P region define a ratio Cₙ₀/Cₚ₀ being greater than 6. In some embodiments, the ratio Cₙ₀/Cₚ₀ ranges between 6 and 16.

Referring to FIGS. 1C and 8C, the method 126 proceeds to an operation 140 by forming a first high-k (HK) dielectric layer 254-1 over the interfacial layer 252 in both N region and P region after the dipole treatment at the operation 138. In some embodiments, the first HK dielectric layer 254-1 includes hafnium oxide (HfO) or zirconium oxide (ZrO). The first HK dielectric layer 254-1 is deposited by ALD, other suitable method or a combination thereof.

Referring to FIGS. 1C and 8D, the method 126 proceeds to an operation 144 by forming a second high-k (HK) dielectric layer 254-2 over the first HK dielectric layer 254-1 in both N region and P region after the dipole treatment at the operation 142. The second HK dielectric layer 254-2 is deposited by ALD, other suitable method or a combination thereof. In some embodiments, the second HK dielectric layer 254-2 includes a HK dielectric material different from that of the first HK dielectric layer 254-1. For example, the first HK dielectric layer 254-1 includes HfO and the second HK dielectric layer 254-2 includes ZrO. In another example, the first HK dielectric layer 254-1 includes ZrO and the second HK dielectric layer 254-2 includes HfO. In some alternative embodiments, the first and second HK dielectric layers 254-1 and 254-2 include a same composition, such as HfO (or ZrO).

Referring to FIGS. 1C and 8E, the method 126 proceeds to an operation 150 by forming a metal layer of a P metal (or simply referred to as a P metal layer) 256-1 on the gate dielectric layer 251 (which includes the interfacial layer 252 and one or more HK dielectric material layer 254) in both the P region and the N region. The P metal layer 256-1 includes an aluminum-free metal material. In some embodiments, the P metal layer 256-1 includes a metal, metal compound with a work function being equal to or greater than 4.7 eV. In the present embodiment, the P metal layer 256-1 is a titanium nitride (TiN) layer. In various embodiments, the P metal layer 256-1 includes titanium nitride (TiN), tantalum nitride (TaN), tungsten nitride (WN) or a combination thereof. The P metal layer 256-1 is deposited by physical vapor deposition (PVD), ALD, other suitable method or a combination thereof.

Referring to FIGS. 1C and 8F, the method 126 may include an operation 152 by forming a fill metal (or bulk metal) layer 256-2 on the P metal layer 256-1. In various embodiments, the fill metal layer 256-2 includes cobalt (Co), tungsten (W), ruthenium (Ru), nickel (Ni), other suitable metals, or combinations thereof. The fill metal layer may include copper (Cu), tungsten (W), aluminum (Al), cobalt (Co), other suitable materials, or combinations thereof. The fill metal layer 256-2 may be formed by PVD, plating, ALD, other suitable method or a combination thereof. In some embodiments, the fill metal layer 256-2 includes a seed layer formed by PVD, and a bulk metal layer formed on the seed layer by plating.

In some embodiments, a glue layer may be formed before the fill layer. In one embodiment, the glue layer is titanium nitride (TiN) layer. In some embodiments, the glue layer completely fills into spacings between channels 244. In some embodiments, the glue layer does not fill into spacing between channels 244 and located in the region outside of sheet-sheet space, as well as in the gate trench above the channel 244. In some embodiments, the fill metal layer 256-2 is only disposed in the gate trench above the channels 244, and the fill metal layer is free from the spacings between the channels. In some embodiments, the numeral 256-2 collectively refers to the glue layer and the fill metal layer disposed on the glue layer. In some embodiments, the glue layer completely fills the spacings between the channels and the gate trench so that the fill metal layer is eliminated and replaced by the glue layer. In this case, the numeral 256-2 represents the glue layer. In various embodiments wherein the glue layer is present, the glue layer contacts the P metal layer 256-1 in the P region and N region.

In some embodiments, the glue layer is located in the gate trench above the first channels and outside of space between two first channels. In some embodiments, a portion of the P metal is located in between HK layer and the glue layer. In some embodiments, the fill metal is located in the gate trench above the first channels and outside of space between two first channels, wherein the fill metal comprises Tungsten.

The method 126 proceeds to an operation 154 by performing a CMP process to remove excessive gate materials and planarize the top surface, as illustrated in FIG. 4G.

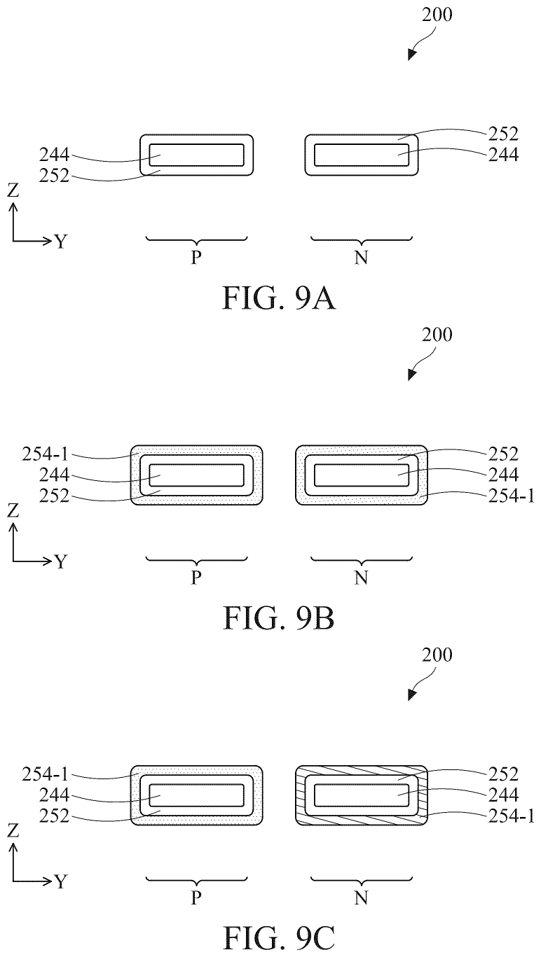

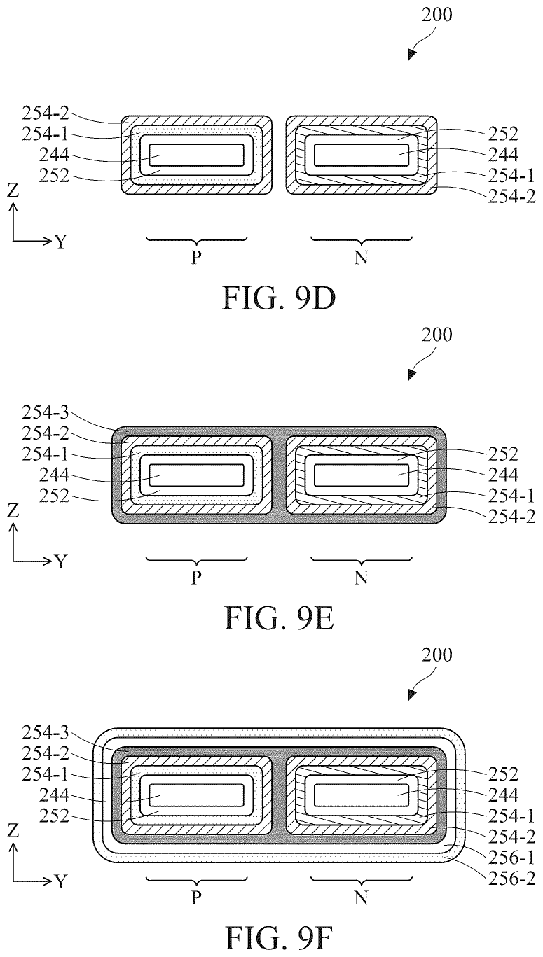

FIG. 1D is a flowchart of the method 126 according to various embodiments. FIGS. 9A through 9H are sectional views of the semiconductor device 200 at various fabrication stages according to some embodiments. Note that only a portion 258 of the semiconductor device 200 in FIG. 4G is illustrated in FIGS. 9A through 9F for simplicity.

Referring to FIGS. 1D and 9A, the method 126 includes an operation 136 by forming an interfacial layer 252 on the channels 244 in both N region and P region. In the disclosed embodiment, the interfacial layer 252 is wrapping around each of the channels 244. The interfacial layer 252 may include silicon oxide, other suitable dielectric material, or a combination thereof. The interfacial layer 252 may be formed by applying a wet solution of hydrochloric acid-hydrogen peroxide-water mixture (SC-2) to the channels 244, thermal oxidation, atomic layer deposition (ALD), other suitable technique or a combination thereof.

Referring to FIGS. 1D and 9B, the method 126 proceeds to an operation 140 by forming a first high-k (HK) dielectric layer 254-1 over the interfacial layer 252 in both N region and P region. In some embodiments, the first HK dielectric layer 254-1 includes hafnium oxide (HfO) or zirconium oxide (ZrO). The first HK dielectric layer 254-1 is deposited by ALD, other suitable method or a combination thereof.

Referring to FIGS. 1D and 9C, the method 126 proceeds to an operation 142 by performing a dipole treatment to the first HK dielectric layer 254-1 in the N region while the P region is not treated. The dipole treatment at the operation 142 is similar to the dipole treatment at the operation 138. In some embodiments, the dipole treatment includes multiple steps: depositing a dipole material layer, such as lanthanum oxide by a suitable method, such as ALD; patterning the dipole layer using a lithography process and etch such that the dipole layer is only remain in the N region; performing a thermal annealing process so that the lanthanum is diffused into the first HK dielectric layer 254-1 in the N region; and etching to remove the dipole layer. In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer, such as LaO, by a suitable method, such as ALD; forming a mask layer using a lithography process and etch such that the dipole layer in the P region is covered while that the dipole layer in the N region is exposed; performing a thermal annealing process so that the lanthanum is diffused into the first HK dielectric layer 254-1 in the N region; removing the mask layer (for example, stripping or plasma ashing to remove the patterned photoresist layer when the patterned photoresist layer is used as the mask layer); and etching to remove the dipole layer. Thus, the first HK dielectric layer 254-1 in the N region is treated and is different from the first HK dielectric layer 254-1 in the P region in composition. Particularly, the first HK dielectric layer 254-1 in the N region includes more lanthanum that the first HK dielectric layer 254-1 in the P region. The lanthanum concentration of the first HK dielectric layer 254-1 in the N region is referred to as Cₙ₁, and the lanthanum concentration of the first HK dielectric layer 254-1 in the P region is referred to as Cₚ₁. In some embodiments, a ratio Cₙ₁/Cₚ₁ is greater than 6. In some embodiments, the ratio Cₙ₁/Cₚ₁ ranges between 6 and 16.

Referring to FIGS. 1D and 9D, the method 126 proceeds to an operation 144 by forming a second high-k (HK) dielectric layer 254-2 over the first HK dielectric layer 254-1 in both N region and P region after the dipole treatment at the operation 142. The second HK dielectric layer 254-2 is deposited by ALD, other suitable method or a combination thereof. In the disclosed embodiment, the first HK dielectric layer 254-1 (before the dipole treatment at the operation 142) and the second HK dielectric layer 254-2 include a same composition, such as both including HfO (or ZrO). The first HK dielectric layer 254-1 after the dipole treatment at the operation 142 includes more lanthanum than the second HK dielectric layer 254-2.

Referring to FIGS. 1D and 9E, the method 126 proceeds to an operation 156 by forming a third high-k (HK) dielectric layer 254-3 over the second HK dielectric layer 254-2 in both N region and P region. The third HK dielectric layer 254-3 is deposited by ALD, other suitable method or a combination thereof. In the disclosed embodiment, the third HK dielectric layer 254-3 includes a HK dielectric material different from that of the second HK dielectric layer 254-2. For example, the second HK dielectric layer 254-2 includes HfO and the third HK dielectric layer 254-3 includes ZrO. In another example, the second HK dielectric layer 254-2 includes ZrO and the third HK dielectric layer 254-3 includes HfO.

Referring to FIGS. 1D and 9F, the method 126 proceeds to an operation 150 by forming a metal layer of a P metal (or simply referred to as a P metal layer) 256-1 on the gate dielectric layer 251 (which includes the interfacial layer 252 and three HK dielectric layers 254-1, 254-2 and 254-3) in both the P region and the N region. The P metal layer 256-1 includes an aluminum-free metal material. In the present embodiment, the P metal layer 256-1 is a titanium nitride (TiN) layer. In various embodiments, the P metal layer 256-1 includes titanium nitride (TiN), tantalum nitride (TaN), tungsten nitride (WN) or a combination thereof. The P metal layer 256-1 is deposited by physical vapor deposition (PVD), ALD, other suitable method or a combination thereof.

Still referring to FIGS. 1D and 9F, the method 126 may include an operation 152 by forming a fill metal (or bulk metal) layer 256-2 on the P metal layer 256-1. In various embodiments, the fill metal layer 256-2 includes cobalt (Co), tungsten (W), ruthenium (Ru), nickel (Ni), other suitable metals, or combinations thereof. The fill metal layer may include copper (Cu), tungsten (W), aluminum (Al), cobalt (Co), other suitable materials, or combinations thereof. The fill metal layer 256-2 may be formed by PVD, plating, ALD, other suitable method or a combination thereof. In some embodiments, the fill metal layer 256-2 includes a seed layer formed by PVD, and a bulk metal layer formed on the seed layer by plating.

The method 126 proceeds to an operation 154 by performing a chemical mechanical polishing (CMP) process to remove excessive gate materials and planarize the top surface, as illustrated in FIG. 4G.

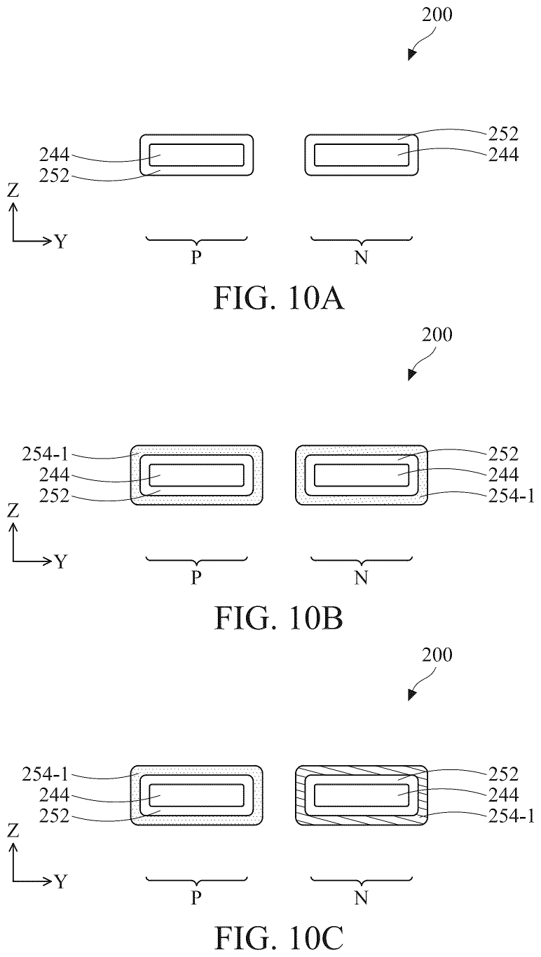

FIG. 1E is a flowchart of the method 126 constructed according to some embodiments. FIGS. 10A through 10F are sectional views of the semiconductor device 200 at various fabrication stages according to some embodiments. Note that only a portion 258 of the semiconductor device 200 in FIG. 4G is illustrated in FIGS. 10A through 10F for simplicity. The method 126 is further described in detail with reference to FIGS. 1E and 10A through 10F.

Referring to FIGS. 1E and 10A, the method 126 includes an operation 136 by forming an interfacial layer 252 on the channels 244 in both N region and P region. In the disclosed embodiment, the interfacial layer 252 is wrapping around each of the channels 244. The interfacial layer 252 may include silicon oxide, other suitable dielectric material, or a combination thereof. The interfacial layer 252 may be formed by applying a wet solution of hydrochloric acid-hydrogen peroxide-water mixture to the channels 244, thermal oxidation, atomic layer deposition (ALD), other suitable technique or a combination thereof.

Referring to FIGS. 1E and 10B, the method 126 proceeds to an operation 140 by forming a first high-k (HK) dielectric layer 254-1 over the interfacial layer 252 in both N region and P region. In some embodiments, the first HK dielectric layer 254-1 includes hafnium oxide (HfO) or zirconium oxide (ZrO). The first HK dielectric layer 254-1 is deposited by ALD, other suitable method or a combination thereof.

Referring to FIGS. 1E and 10C, the method 126 proceeds to an operation 142 by performing a dipole treatment to the first HK dielectric layer 254-1 in the N region while the P region is not treated. The dipole treatment at the operation 142 is similar to the dipole treatment at the operation 138. In some embodiments, the dipole treatment includes multiple steps: depositing a dipole material layer, such as lanthanum oxide by a suitable method, such as ALD; patterning the dipole layer using a lithography process and etch such that the dipole layer is only remain in the N region; performing a thermal annealing process so that the lanthanum is diffused into the first HK dielectric layer 254-1 in the N region; and etching to remove the dipole layer. In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer, such as LaO, by a suitable method, such as ALD; forming a mask layer using a lithography process and etch such that the dipole layer in the P region is covered while that the dipole layer in the N region is exposed; performing a thermal annealing process so that the lanthanum is diffused into the first HK dielectric layer 254-1 in the N region; removing the mask layer (for example, stripping or plasma ashing to remove the patterned photoresist layer when the patterned photoresist layer is used as the mask layer); and etching to remove the dipole layer. Thus, the first HK dielectric layer 254-1 in the N region is treated and is different from the first HK dielectric layer 254-1 in the P region in composition. Particularly, the first HK dielectric layer 254-1 in the N region includes more lanthanum that the first HK dielectric layer 254-1 in the P region. In some embodiments, the lanthanum concentration Cₙ₀ of the interfacial layer 252 in the N region and the lanthanum concentration Cₚ₀ of the interfacial layer 252 in the P region define a ratio Cₙ₀/Cₚ₀ being greater than 6. In some embodiments, the ratio Cₙ₀/Cₚ₀ ranges between 6 and 16.

Referring to FIGS. 1E and 10D, the method 126 proceeds to an operation 144 by forming a second high-k (HK) dielectric layer 254-2 over the first HK dielectric layer 254-1 in both N region and P region after the dipole treatment at the operation 142. The second HK dielectric layer 254-2 is deposited by ALD, other suitable method or a combination thereof. In the disclosed embodiments, the second HK dielectric layer 254-2 includes a HK dielectric material different from that of the first HK dielectric layer 254-1 when it is deposited and before the dipole treatment at the operation 142. For example, the first HK dielectric layer 254-1 includes HfO and the second HK dielectric layer 254-2 includes ZrO. In another example, the first HK dielectric layer 254-1 includes ZrO and the second HK dielectric layer 254-2 includes HfO.

Referring to FIGS. 1E and 10E, the method 126 proceeds to an operation 150 by forming a metal layer of a P metal (or simply referred to as a P metal layer) 256-1 on the gate dielectric layer 251 (which includes the interfacial layer 252 and two HK dielectric layers 254-1 and 254-2) in both the P region and the N region. The P metal layer 256-1 includes an aluminum-free metal material. In the present embodiment, the P metal layer 256-1 is a titanium nitride (TiN) layer. In various embodiments, the P metal layer 256-1 includes titanium nitride (TiN), titanium-silicon nitride (TiSiN), molybdenum nitride (MoN), tantalum nitride (TaN), tungsten nitride (WN) or a combination thereof. The P metal layer 256-1 is deposited by physical vapor deposition (PVD), ALD, other suitable method or a combination thereof.

Referring to FIGS. 1E and 10F, the method 126 may include an operation 152 by forming a fill metal (or bulk metal) layer 256-2 on the P metal layer 256-1. In various embodiments, the fill metal layer 256-2 includes cobalt (Co), tungsten (W), ruthenium (Ru), nickel (Ni), other suitable metals, or combinations thereof. The fill metal layer may include copper (Cu), tungsten (W), aluminum (Al), cobalt (Co), other suitable materials, or combinations thereof. The fill metal layer 256-2 may be formed by PVD, plating, ALD, other suitable method or a combination thereof. In some embodiments, the fill metal layer 256-2 includes a seed layer formed by PVD, and a bulk metal layer formed on the seed layer by plating.

The method 126 proceeds to an operation 154 by performing a chemical mechanical polishing (CMP) process to remove excessive gate materials and planarize the top surface, as illustrated in FIG. 4G.

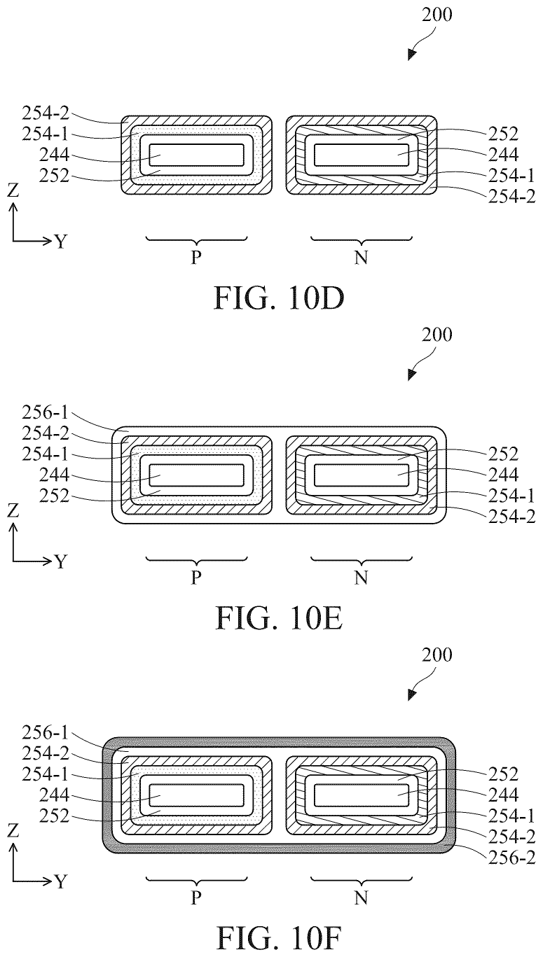

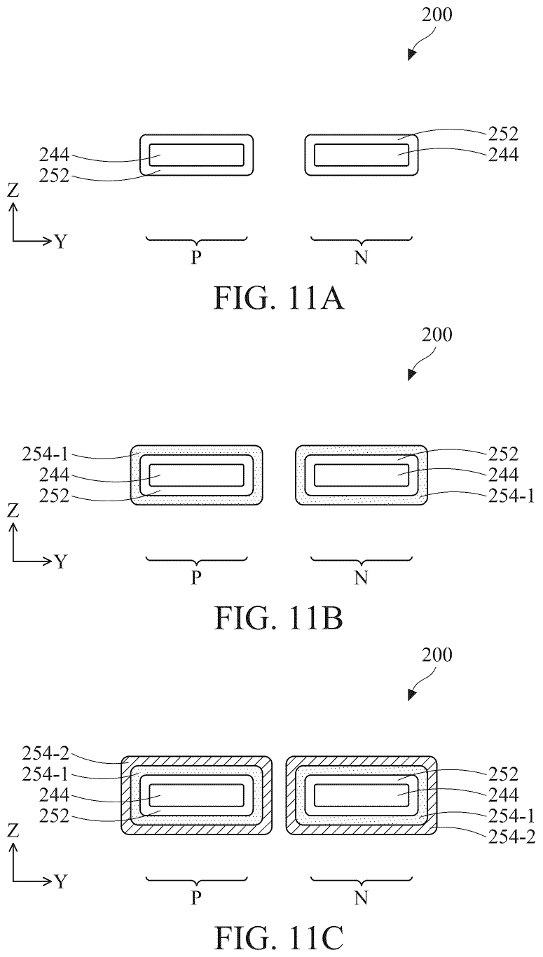

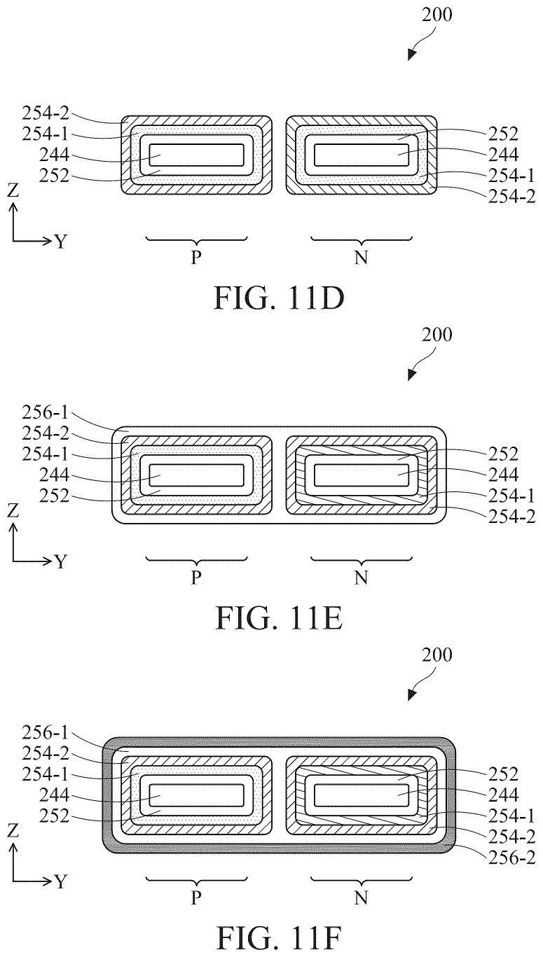

FIG. 1F is a flowchart of the method 126 constructed according to some embodiments. FIGS. 11A through 11F are sectional views of the semiconductor device 200 at various fabrication stages according to some embodiments. Note that only a portion 258 of the semiconductor device 200 in FIG. 4G is illustrated in FIGS. 11A through 11F for simplicity. The method 126 is further described in detail with reference to FIGS. 1F and 11A through 11F.

Referring to FIGS. 1F and 11A, the method 126 includes an operation 136 by forming an interfacial layer 252 on the channels 244 in both N region and P region. In the disclosed embodiment, the interfacial layer 252 is wrapping around each of the channels 244. The interfacial layer 252 may include silicon oxide, other suitable dielectric material, or a combination thereof. The interfacial layer 252 may be formed by applying a wet solution of hydrochloric acid-hydrogen peroxide-water mixture (SC-2) to the channels 244, thermal oxidation, atomic layer deposition (ALD), other suitable technique or a combination thereof.

Referring to FIGS. 1F and 11B, the method 126 proceeds to an operation 140 by forming a first high-k (HK) dielectric layer 254-1 over the interfacial layer 252 in both N region and P region. In some embodiments, the first HK dielectric layer 254-1 includes hafnium oxide (HfO) or zirconium oxide (ZrO). The first HK dielectric layer 254-1 is deposited by ALD, other suitable method or a combination thereof.

Referring to FIGS. 1F and 11C, the method 126 proceeds to an operation 144 by forming a second high-k (HK) dielectric layer 254-2 over the first HK dielectric layer 254-1 in both N region and P region after the dipole treatment at the operation 142. The second HK dielectric layer 254-2 is deposited by ALD, other suitable method or a combination thereof. In the disclosed embodiments, the second HK dielectric layer 254-2 includes a HK dielectric material different from that of the first HK dielectric layer 254-1 when it is deposited and before the dipole treatment at the operation 142. For example, the first HK dielectric layer 254-1 includes HfO and the second HK dielectric layer 254-2 includes ZrO. In another example, the first HK dielectric layer 254-1 includes ZrO and the second HK dielectric layer 254-2 includes HfO.

Referring to FIGS. 1F and 11D, the method 126 proceeds to an operation 146 by performing a dipole treatment to the second HK dielectric layer 254-2 in the N region while the P region is not treated. In some embodiments, the dipole treatment includes multiple steps: depositing a dipole material layer, such as lanthanum oxide by a suitable method, such as ALD; patterning the dipole layer using a lithography process and etch such that the dipole layer is only remain in the N region; performing a thermal annealing process so that the lanthanum is diffused into the second HK dielectric layer 254-2 in the N region; and etching to remove the dipole layer. In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer, such as LaO, by a suitable method, such as ALD; forming a mask layer using a lithography process and etch such that the dipole layer in the P region is covered while that the dipole layer in the N region is exposed; performing a thermal annealing process so that the lanthanum is diffused into the second HK dielectric layer 254-2 in the N region; removing the mask layer (for example, stripping or plasma ashing to remove the patterned photoresist layer when the patterned photoresist layer is used as the mask layer); and etching to remove the dipole layer. Thus, the first HK dielectric layer 254-1 in the N region is treated and is different from the second HK dielectric layer 254-2 in the P region in composition. Particularly, the second HK dielectric layer 254-2 in the N region includes more lanthanum that the second HK dielectric layer 254-2 in the P region. The lanthanum concentration of the second HK dielectric layer 254-2 in the N region is referred to as Cₙ₂, and the lanthanum concentration of the second HK dielectric layer 254-2 in the P region is referred to as Cₚ₂. In some embodiments, a ratio Cₙ₂/Cₚ₂ is greater than 6. In some embodiments, the ratio Cₙ₂/Cₚ₂ ranges between 6 and 16.

Referring to FIGS. 1F and 11E, the method 126 proceeds to an operation 150 by forming a metal layer of a P metal (or simply referred to as a P metal layer) 256-1 on the gate dielectric layer 251 (which includes the interfacial layer 252 and two HK dielectric layers 254-1 and 254-2) in both the P region and the N region. The P metal layer 256-1 includes an aluminum-free metal material. In the present embodiment, the P metal layer 256-1 is a titanium nitride (TiN) layer. In various embodiments, the P metal layer 256-1 includes titanium nitride (TiN), titanium-silicon nitride (TiSiN), molybdenum nitride (MoN), tantalum nitride (TaN), tungsten nitride (WN) or a combination thereof. The P metal layer 256-1 is deposited by physical vapor deposition (PVD), ALD, other suitable method or a combination thereof.

Referring to FIGS. 1F and 11F, the method 126 may include an operation 152 by forming a fill metal (or bulk metal) layer 256-2 on the P metal layer 256-1. In various embodiments, the fill metal layer 256-2 includes cobalt (Co), tungsten (W), ruthenium (Ru), nickel (Ni), other suitable metals, or combinations thereof. The fill metal layer may include copper (Cu), tungsten (W), aluminum (Al), cobalt (Co), other suitable materials, or combinations thereof. The fill metal layer 256-2 may be formed by PVD, plating, ALD, other suitable method or a combination thereof. In some embodiments, the fill metal layer 256-2 includes a seed layer formed by PVD, and a bulk metal layer formed on the seed layer by plating.

The method 126 proceeds to an operation 154 by performing a chemical mechanical polishing (CMP) process to remove excessive gate materials and planarize the top surface, as illustrated in FIG. 4G.

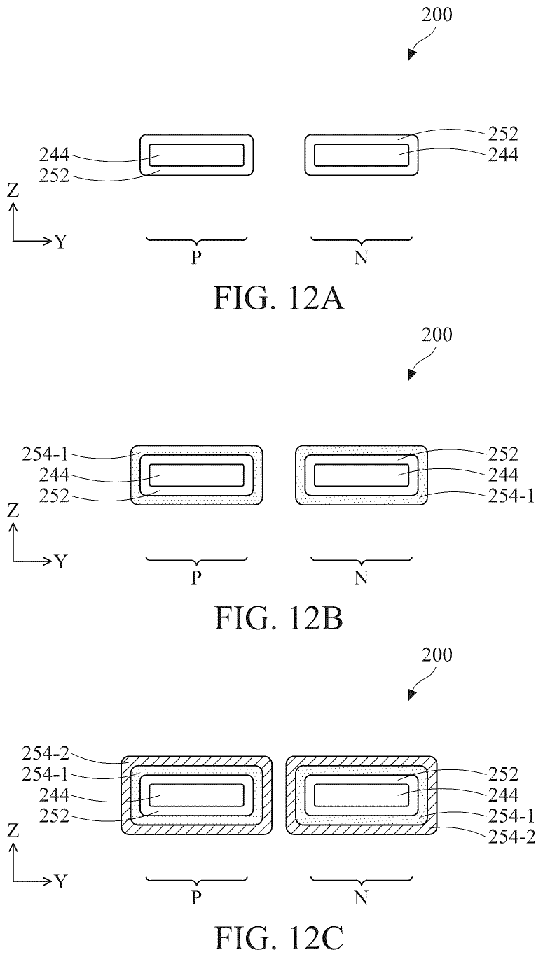

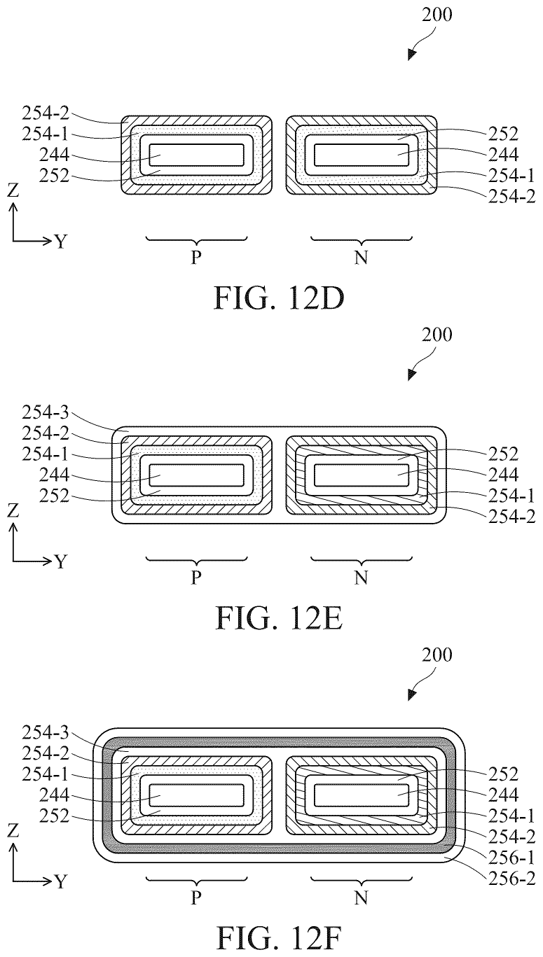

FIG. 1G is a flowchart of the method 126 constructed according to some embodiments. FIGS. 12A through 12F are sectional views of the semiconductor device 200 at various fabrication stages according to some embodiments. Note that only a portion 258 of the semiconductor device 200 in FIG. 4G is illustrated in FIGS. 12A through 12F for simplicity. The method 126 is further described in detail with reference to FIGS. 1G and 12A through 12F.

Referring to FIGS. 1G and 12A, the method 126 includes an operation 136 by forming an interfacial layer 252 on the channels 244 in both N region (“N” in FIG. 7A) and P region (“P” in FIG. 7A). In the disclosed embodiment, the interfacial layer 252 is wrapping around each of the channels 244. The interfacial layer 252 may include silicon oxide, other suitable dielectric material, or a combination thereof. The interfacial layer 252 may be formed by applying a wet solution of hydrochloric acid-hydrogen peroxide-water mixture to the channels 244, thermal oxidation, atomic layer deposition (ALD), other suitable technique or a combination thereof.

Referring to FIGS. 1G and 12B, the method 126 proceeds to an operation 140 by forming a first high-k (HK) dielectric layer 254-1 over the interfacial layer 252 in both N region and P region after the dipole treatment at the operation 138. In some embodiments, the first HK dielectric layer 254-1 includes hafnium oxide (HfO) or zirconium oxide (ZrO). The first HK dielectric layer 254-1 is deposited by ALD, other suitable method or a combination thereof.

Referring to FIGS. 1G and 12C, the method 126 proceeds to an operation 144 by forming a second high-k (HK) dielectric layer 254-2 over the first HK dielectric layer 254-1 in both N region and P region. The second HK dielectric layer 254-2 is deposited by ALD, other suitable method or a combination thereof. In the disclosed embodiment, the second HK dielectric layer 254-2 includes a HK dielectric material different from that of the first HK dielectric layer 254-1. For example, the first HK dielectric layer 254-1 includes HfO and the second HK dielectric layer 254-2 includes ZrO. In another example, the first HK dielectric layer 254-1 includes ZrO and the second HK dielectric layer 254-2 includes HfO.

Referring to FIGS. 1G and 12D, the method 126 proceeds to an operation 146 by performing a dipole treatment to the second HK dielectric layer 254-2 in the N region while the P region is not treated. In some embodiments, the dipole treatment includes multiple steps: depositing a dipole material layer, such as lanthanum oxide by a suitable method, such as ALD; patterning the dipole layer using a lithography process and etch such that the dipole layer is only remain in the N region; performing a thermal annealing process so that the lanthanum is diffused into the second HK dielectric layer 254-2 in the N region; and etching to remove the dipole layer. In some embodiments, the thermal annealing process includes a thermal annealing temperature ranging 550° C. and 1050° C.; an annealing duration ranging between 5 seconds and 5 minutes; and an annealing gas. The annealing gas may include an inert gas, such as argon, nitrogen, other inert gas or a combination thereof. In some embodiments, the dipole treatment includes multiple steps: depositing a dipole material layer by a suitable method, such as ALD; forming a mask layer using a lithography process and etch such that the dipole layer in the P region is covered while that the dipole layer in the N region is exposed; performing a thermal annealing process so that the lanthanum is diffused into the second HK dielectric layer 254-2 in the N region; removing the mask layer (for example, stripping or plasma ashing to remove the patterned photoresist layer when the patterned photoresist layer is used as the mask layer); and etching to remove the dipole layer. Thus, the second HK dielectric layer 254-2 in the N region is treated and includes lanthanum. The lanthanum concentration of the second HK dielectric layer 254-2 in the N region is referred to as Cₙ₂, and the lanthanum concentration of the second HK dielectric layer 254-2 in the P region is referred to as Cₚ₂. In some embodiments, a ratio Cₙ₂/Cₚ₂ is greater than 6. In some embodiments, the ratio Cₙ₂/Cₚ₂ ranges between 6 and 16.

Referring to FIGS. 1G and 12E, the method 126 proceeds to an operation 156 by forming a third high-k (HK) dielectric layer 254-3 over the second HK dielectric layer 254-2 in both N region and P region. The third HK dielectric layer 254-3 is deposited by ALD, other suitable method or a combination thereof. In the disclosed embodiment, the third HK dielectric layer 254-3 includes a HK dielectric material different from that of the first HK dielectric layer 254-1 but as the same that of the second HK dielectric layer 254-2 before being dipole treated at the operation 146. For example, the first HK dielectric layer 254-1 includes HfO while the second and third HK dielectric layers 254-2 and 354-3 include ZrO. In another example, the first HK dielectric layer 254-1 includes ZrO while the second and third HK dielectric layers 254-2 and 254-3 include HfO. Note that the second and third HK dielectric layers 254-2 and 254-3 are different from each other after the dipole treatment at the operation 146 since the second HK dielectric layer 254-2 has more lanthanum than the third HK dielectric layer 25-3. For example, both the second and third HK dielectric layers 254-2 and 354-3 include ZrO but the third HK dielectric layer 354-3 includes more lanthanum than the second HK dielectric layer 254-2. In another example, both the second and third HK dielectric layers 254-2 and 354-3 include HfO but the third HK dielectric layer 354-3 includes more lanthanum than the second HK dielectric layer 254-2.

Referring to FIGS. 1G and 12F, the method 126 proceeds to an operation 150 by forming a metal layer of a P metal (or simply referred to as a P metal layer) 256-1 on the gate dielectric layer 251 (which includes the interfacial layer 252 and three HK dielectric layers 254-1, 254-2 and 254-3) in both the P region and the N region. The P metal layer 256-1 includes an aluminum-free metal material. In some embodiments, the P metal layer 256-1 includes a metal, metal compound with a work function being equal to or greater than 4.7 eV. In the present embodiment, the P metal layer 256-1 is a titanium nitride (TiN) layer. In various embodiments, the P metal layer 256-1 includes titanium nitride (TiN), titanium-silicon nitride (TiSiN), molybdenum nitride (MoN), tantalum nitride (TaN), tungsten nitride (WN) or a combination thereof. The P metal layer 256-1 is deposited by physical vapor deposition (PVD), ALD, other suitable method or a combination thereof.

Still referring to FIGS. 1G and 12F, the method 126 may include an operation 152 by forming a fill metal (or bulk metal) layer 256-2 on the P metal layer 256-1. In various embodiments, the fill metal layer 256-2 includes cobalt (Co), tungsten (W), ruthenium (Ru), nickel (Ni), other suitable metals, or combinations thereof. The fill metal layer may include copper (Cu), tungsten (W), aluminum (Al), cobalt (Co), other suitable materials, or combinations thereof. The fill metal layer 256-2 may be formed by PVD, plating, ALD, other suitable method or a combination thereof. In some embodiments, the fill metal layer 256-2 includes a seed layer formed by PVD, and a bulk metal layer formed on the seed layer by plating.

The method 126 proceeds to an operation 154 by performing a chemical mechanical polishing (CMP) process to remove excessive gate materials and planarize the top surface, as illustrated in FIG. 4G.

In summary, the present disclosure provides a method to form a semiconductor device having a GAA structure with a method using dummy interposers and a formation of a gate structure using dipole treatment and single work function metal on both P and N regions. Although not intended to be limiting, one or more embodiments of the present disclosure provide many benefits to a semiconductor device and the formation thereof. The present disclosure provides methods of forming a GAA device with an engineered metal gate structure. The formation of the metal gate structure is designed to effectively eliminate various issues, such as HK dielectric reliability issue, HK dielectric loss, and metal boundary effect. The disclosed method includes depositing only one type-work function metal layer in both regions for nFETs and pFETs and performing one or more dipole treatment to the gate dielectric layer in only one of N region and P region, thereby tuning the work function of the gate dielectric layer in that region. Collectively, the threshold voltages for both nFETs and pFETs are reduced and optimized.

In one example aspect, the present disclosure provides a method that includes providing a substrate having a N region for n-type field-effect transistors (nFETs) and a P region for p-type field-effect transistors (pFETs); forming a semiconductor fin protruding from the substrate, the semiconductor fin including a plurality of first semiconductor layers of a first semiconductor material and second semiconductor layers of a second semiconductor material alternatively stacked, the second semiconductor material being different from the first semiconductor material in composition; forming a first gate stack on the semiconductor fin; forming a recess in the semiconductor fin within a source/drain (S/D) region adjacent to the first gate stack; performing an etching process to selectively remove the second semiconductor layers, resulting in gaps among the first semiconductor layers; filling in the gaps with a dielectric material to form dummy interposers; epitaxially growing a S/D feature from the recess; removing the first gate stack, resulting in a gate trench; performing an etching process to remove the dummy interposers through the gate trench; forming a gate dielectric layer to wrap around the first semiconductor layers; performing a dipole treatment to a first portion of the gate dielectric layer in the N region while a second portion of the gate dielectric layer in the P region remain untreated; and depositing a P metal layer in the gate dielectric layer in both the P region and the N region.

In another example aspect, the present disclosure provides a method that includes providing a substrate having a N region for n-type field-effect transistors (nFETs) and a P region for p-type field-effect transistors (pFETs); forming a gate dielectric layer in the N region and the P region to wrap around channels vertically stacked; performing a dipole treatment to a first portion of the gate dielectric layer in the N region while a second portion of the gate dielectric layer in the P region remain untreated; depositing a P metal layer in the gate dielectric layer in both the P region and the N region; and forming a fill metal layer on the P metal layer in both the P region and the N region.

In yet another example aspect, the present disclosure provides a semiconductor structure that includes a substrate having a N region for a n-type field effect transistor (nFET) and a P region for a p-type field effect transistor (pFET); a first channel region disposed on the N region of the substrate and a second channel region disposed on the P region of the substrate, wherein the first channel region includes a plurality of first channels vertically stacked over one another, and the second channel region includes a plurality of second channels vertically stacked over one another; a first source/drain (S/D) region located adjacent to the first channel region and a second source/drain (S/D) region located adjacent to the second channel region; and a gate stack disposed on the first and second channel region. The gate stack includes a gate dielectric layer and a gate electrode disposed on the gate dielectric layer, the gate dielectric layer includes a first portion in the P region and a second portion in the N region, the first portion of the gate dielectric layer includes a first lanthanum concentration Cp and is engaging the first channel region and surrounding each of the first channels, the second portion of the gate dielectric layer includes a second lanthanum concentration Cn and is engaging the second channel region and surrounding each of the second channels, Cn being greater than Cp, the gate electrode includes a P metal layer disposed on the gate dielectric layer, and the P metal layer extends from the P region to the N region.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
providing a substrate having a N region for n-type field-effect transistors (nFETs) and a P region for p-type field-effect transistors (pFETs);
forming a semiconductor fin protruding from the substrate, the semiconductor fin including a plurality of first semiconductor layers of a first semiconductor material and second semiconductor layers of a second semiconductor material alternatively stacked, the second semiconductor material being different from the first semiconductor material in composition;
forming a first gate stack on the semiconductor fin;
forming a recess in the semiconductor fin within a source/drain (S/D) region adjacent to the first gate stack;
performing an etching process to selectively remove the second semiconductor layers, resulting in gaps among the first semiconductor layers;
filling in the gaps with a dielectric material to form dummy interposers;
epitaxially growing a S/D feature from the recess;
removing the first gate stack, resulting in a gate trench;
performing an etching process to remove the dummy interposers through the gate trench;
forming a gate dielectric layer to wrap around the first semiconductor layers;
performing a dipole treatment to a first portion of the gate dielectric layer in the N region while a second portion of the gate dielectric layer in the P region remain untreated; and
depositing a P metal layer in the gate dielectric layer in both the P region and the N region.

2. The method of claim 1, wherein the performing of the dipole treatment to the first portion of the gate dielectric layer in the N region includes
depositing a dipole material layer on the gate dielectric layer in both the N region and the P region;
patterning the dipole material layer so that a portion of the dipole material layer in the P region is removed;
perform a thermal annealing process so that the dipole material layer diffuses into the gate dielectric layer in the N region; and
etching to remove the dipole material layer.

3. The method of claim 2, wherein the dipole material layer is a lanthanum oxide layer.

4. The method of claim 2, after the performing of the dipole treatment to the first portion of the gate dielectric layer in the N region while the second portion of the gate dielectric layer in the P region remain untreated, wherein
the first portion of the gate dielectric layer in the N region includes a first lanthanum concentration Cn;
the second portion of the gate dielectric layer in the P region includes a second lanthanum concentration Cp; and
a ratio Cn/Cp is greater than 6.

5. The method of claim 2, wherein the forming of the gate dielectric layer to wrap around the first semiconductor layers further includes
depositing an interfacial layer;
depositing a first high-K dielectric layer on the interfacial layer; and
depositing a second high-K dielectric layer on the first high-K dielectric layer, wherein the second high-K dielectric layer is different from the first high-K dielectric layer in composition, wherein the first high-K dielectric layer includes hafnium oxide; and the second high-K dielectric layer includes zirconium oxide.

6. The method of claim 5, wherein the performing of the dipole treatment to the first portion of the gate dielectric layer in the N region while the second portion of the gate dielectric layer in the P region remain untreated includes performing the dipole treatment to the interfacial layer before the depositing of the first high-K dielectric layer on the interfacial layer.

7. The method of claim 5, wherein the performing of the dipole treatment to the first portion of the gate dielectric layer in the N region while the second portion of the gate dielectric layer in the P region remain untreated includes performing the dipole treatment to the first high-K dielectric layer before the depositing of the second high-K dielectric layer on the first high-K dielectric layer.

8. The method of claim 5, wherein the performing of the dipole treatment to the first portion of the gate dielectric layer in the N region while the second portion of the gate dielectric layer in the P region remain untreated includes performing the dipole treatment to the second high-K dielectric layer after the depositing of the second high-K dielectric layer on the first high-K dielectric layer.

9. The method of claim 1, wherein the depositing of the P metal layer on the gate dielectric layer on both the P region and the N region includes depositing a titanium nitride layer on the gate dielectric layer in both the P region and the N region.

10. The method of claim 1, wherein
the first semiconductor material includes silicon;
the second semiconductor material includes silicon germanium; and
the dummy interposers include silicon oxide.

11. A method, comprising:
providing a substrate having a N region for n-type field-effect transistors (nFETs) and a P region for p-type field-effect transistors (pFETs);
forming a gate dielectric layer in the N region and the P region to wrap around channels vertically stacked;
performing a dipole treatment to a first portion of the gate dielectric layer in the N region while a second portion of the gate dielectric layer in the P region remain untreated;
depositing a P metal layer in the gate dielectric layer in both the P region and the N region; and
forming a fill metal layer on the P metal layer in both the P region and the N region.

12. The method of claim 11, further comprising:
forming a semiconductor fin protruding from the substrate, the semiconductor fin including a plurality of first semiconductor layers of silicon and second semiconductor layers of silicon germanium alternatively stacked, wherein the forming of the gate dielectric layer on the N region and the P region to wrap around the channels vertically stacked includes forming the gate dielectric layer on the semiconductor fin in the N region and the P region;
forming a dummy gate stack on the semiconductor fin;
forming a recess in the semiconductor fin within a source/drain (S/D) region adjacent to the dummy gate stack;
performing an etching process to selectively remove the second semiconductor layers, resulting in gaps among the first semiconductor layers;
filling in the gaps with a dielectric material to form dummy interposers;
laterally recessing the dummy interposers, resulting in undercuts among the first semiconductor layers;
forming inner spacers in the undercuts;
epitaxially growing a S/D feature from the recess;
removing the dummy gate stack, resulting in a gate trench;
performing an etching process to remove the dummy interposers through the gate trench; and
forming a glue layer of titanium nitride interposed between the P metal layer and the fill metal layer.

13. The method of claim 11, wherein the performing of the dipole treatment to the first portion of the gate dielectric layer in the N region includes
depositing a lanthanum oxide layer on the gate dielectric layer in both the N region and the P region;
patterning the lanthanum oxide layer so that a portion of the lanthanum oxide layer in the P region is removed;
perform a thermal annealing process so that lanthanum of the lanthanum oxide layer diffuses into the gate dielectric layer in the N region; and
etching to remove the lanthanum oxide layer.

14. The method of claim 13, wherein
a lanthanum concentration Cn of the first portion of the gate dielectric layer in the N region, a lanthanum concentration Cp of the second portion of the gate dielectric layer in the P region, and a ratio Cn/Cp is greater than 6; and
the P metal layer is a titanium nitride layer.

15. The method of claim 11, wherein the forming of the gate dielectric layer in the N region and the P region to wrap around the channels vertically stacked includes:
depositing an interfacial layer;
depositing a first high-K dielectric layer on the interfacial layer; and
depositing a second high-K dielectric layer on the first high-K dielectric layer, wherein a first one of the first high-K dielectric layer and the second high-K dielectric layer includes hafnium oxide, and a second one of the first high-K dielectric layer and the second high-K dielectric layer includes zirconium oxide.

16. The method of claim 15, wherein the performing of the dipole treatment to the first portion of the gate dielectric layer in the N region while the second portion of the gate dielectric layer in the P region remain untreated includes performing the dipole treatment to the first high-K dielectric layer before the depositing of the second high-K dielectric layer on the first high-K dielectric layer.

17. A semiconductor structure, comprising:
a substrate having a N region for a n-type field effect transistor (nFET) and a P region for a p-type field effect transistor (pFET);
a first channel region disposed on the N region of the substrate and a second channel region disposed on the P region of the substrate, wherein the first channel region includes a plurality of first channels vertically stacked over one another, and the second channel region includes a plurality of second channels vertically stacked over one another;
a first source/drain (S/D) region located adjacent to the first channel region and a second source/drain (S/D) region located adjacent to the second channel region; and
a gate stack disposed on the first and second channel region, wherein
the gate stack includes a gate dielectric layer and a gate electrode disposed on the gate dielectric layer,
the gate dielectric layer includes a first portion in the P region and a second portion in the N region,
the first portion of the gate dielectric layer includes a first lanthanum concentration Cp and is engaging the first channel region and surrounding each of the first channels,
the second portion of the gate dielectric layer includes a second lanthanum concentration Cn and is engaging the second channel region and surrounding each of the second channels, Cn being greater than Cp,
the gate electrode includes a P metal layer disposed on the gate dielectric layer, and
the P metal layer extends from the P region to the N region.

18. The semiconductor structure of claim 17, further comprising a glue layer located in a gate trench above the first channels and outside of space between two first channels.

19. The semiconductor structure of claim 18, wherein a portion of the P metal layer is located in between HK layer and the glue layer.

20. The semiconductor structure of claim 17, further comprising a fill metal located in the gate trench above the first channels and outside of space between two first channels, wherein the fill metal comprises Tungsten.
